(19) United States
(12) Patent Application Publication
(10) Pub. No.: US 2024/0030356 A1
(43) Pub. Date: Jan. 25, 2024

(54) SUPER-HETEROJUNCTION SCHOTTKY DIODE

(71) Applicant: The Penn State Research Foundation, University Park, PA (US)

(72) Inventors: Sang-Woo Han, University Park, PA (US); Jianan Song, University Park, PA (US); Rongming Chu, University Park, PA (US); Mansura Sadek, University Park, PA (US)

(21) Appl. No.: 18/247,753

(22) PCT Filed: Oct. 5, 2021
(86) PCT No.: PCT/US2021/053461

§ 371 Date: Apr. 4, 2023

Related U.S. Application Data
(60) Provisional application No. 63/088,048, filed on Oct. 6, 2020.

(51) Int. Cl. H01L 29/872; H01L 29/06; H01L 29/66; H01L 29/778; H01L 29/78

(52) U.S. Cl. CPC H01L 29/872; H01L 29/0634; H01L 29/66212; H01L 29/7788; H01L 29/7806

(57) ABSTRACT

Embodiments relate a super-heterojunction structure. A n-type modulation doping with barrier layer induces a two-dimensional electron gas (2DEG) channel and allows for vertically stacked channels without risk of reaching critical thickness limited by the strain in epitaxy. The n-type modulation doped layer is adjacent the at least one p-type layer to generate a charge balanced super-heterojunction region. A p-type ohmic contact ensures that the processes of depleting and accumulating of electrons and holes in the structure are fast enough for practical switching operation.

### CROSS-REFERENCE TO RELATED APPLICATIONS

This application is related to and claims the benefit of priority to U.S. provisional application No. 63/008,048, filed on Oct. 6, 2020, the entire contents of which are incorporated herein by reference.

### STATEMENT REGARDING FEDERALLY SPONSORED RESEARCH OR DEVELOPMENT

This invention was made with government support under Grant No. DE-AR0001008 awarded by the Department of Energy (AR-PA-E). The Government has certain rights in the invention.

### FIELD OF THE INVENTION

Embodiments relate to a super-heterojunction GaN/AlGaN/GaN structure that allows for vertically stacked channels without risk of reaching critical thickness limited by the strain in epitaxy, generate a charge balanced region for rectangular e-field shape along the device, and further ensures that the processes of depleting and accumulating electrons and holes in the structure are fast enough for practical power switching applications.

### BACKGROUND OF THE INVENTION

With known single-channel AlGaN/GaN structures, polarization field tilts the energy band, resulting in the transfer of electrons from surface donors to the AlGaN/GaN heterojunction, forming a high-density 2D electron gas (2DEG) channel. However, in case of stacking for multiple 2DEG channel, surface donors cannot contribute sufficient and equal amount of electrons to each 2DEG channel in a GaN/AlGaN/GaN structure where the 2DEG channel is far away from the surface. The natural superjunction concept where polarization induce 2DEG and 2D hole gas (2DHG) pairs in a single-as well as multi-channel GaN/AlGaN/GaN heterostructures could achieve low n resistance and high breakdown characteristics. However, stacking multiple layer of thick AlGaN layer with large Al composition, which is needed to generate the 2DHG-2DEG pair, exceeds the critical thickness and causes film cracking.

### SUMMARY OF THE INVENTION

Embodiments relate to a super-heterojunction structure including a channel. The channel comprises a p-doped upper GaN layer (upper p-GaN layer), a p-doped lower GaN layer (lower p-GaN layer), and a p-doped AlGaN layer (p-AlGaN layer) between the upper p-GaN layer and the lower p-GaN layer. The channel further comprises an interface at the upper p-GaN layer and the p-AlGaN layer, the interface including a n-type delta doped GaN layer (delta-nGaN layer).

In some embodiments, super-heterojunction structure includes a plurality of channels.

Some embodiments of the super-heterojunction structure include an upper channel, at least one intermediate channel, and a lower channel. For the upper channel, its lower p-GaN layer serves as an upper p-GaN layer for an intermediate channel adjacent the upper channel. For the lower channel, its upper p-GaN layer serves as a lower p-GaN layer for an intermediate channel adjacent the lower channel. The upper p-GaN layer of an intermediate channel serves as a lower p-GaN layer for an adjacent intermediate channel, and the lower p-GaN layer for an intermediate channel serves as an upper p-GaN layer for an adjacent intermediate channel.

In some embodiments of the super-heterojunction structure, the plurality of channels are arranged in a stack. Each upper p-GaN layer has a top surface and a bottom surface, and a distance between the top and bottom surfaces is a width of the upper p-GaN layer. Each lower p-GaN layer has a top surface and a bottom surface, and a distance between the top and bottom surfaces is a width of the lower p-GaN layer. The upper p-GaN layer of the upper channel has a width <any of the widths of any upper or lower pGaN layers of any intermediate channel. The lower p-GaN layer of the lower channel has a width <any of the widths of any upper or lower p-GaN layers of any intermediate channel.

In some embodiments, Mg is used as the p-type dopant for the upper p-GaN layer, the lower p-GaN layer, and/or the p-AlGaN layer.

Embodiments can relate to a diode. The diode can include a super-heterojunction structure. The super-heterojunction structure comprises an upper channel, at least one intermediate channel, and a lower channel. Each of the upper channel, the at least one intermediate channel, and the lower channel includes a p-doped upper GaN layer (upper p-GaN layer), a p-doped lower GaN layer (lower p-GaN layer), and a p-doped AlGaN layer (p-AlGaN layer) between the upper p-GaN layer and the lower p-GaN layer. Each channel includes an interface at the upper p-GaN layer and the p-AlGaN layer, the interface including a n-type delta doped GaN layer (delta-nGaN layer). The upper channel, the at least one intermediate channel, and the lower channel are arranged in a stack having a first side and a second side. The diode includes an anode formed on the first side. The diode includes a cathode formed on the second side.

In some embodiments, the anode is a p-type ohmic anode.

In some embodiments, the p-type ohmic anode is configured to form a p-type ohmic contact for each upper p-GaN layer and lower p-GaN layer.

In some embodiments, the diode includes a passivation layer.

Some embodiments relate to a transistor comprising two diodes, at least one diode being an embodiment of a diode disclosed herein.

In some embodiments, Mg is used as the p-type dopant for the upper p-GaN layer, the lower p-GaN layer, and/or the p-AlGaN layer.

Embodiments can relate to a diode. The diode can include a super-heterojunction structure. The super-heterojunction structure comprises a stack of layers having a first side and a second side. The stack includes a p+GaN layer, a pGaN layer adjacent the p+GaN layer, an unintentionally doped (UID) GaN spacer layer adjacent the pGaN layer, an AlGaN layer adjacent the UID GaN spacer layer, an UID GaN channel layer adjacent the AlGaN layer, a GaN buffer layer adjacent the UID GaN channel layer, and an interface at the UID GaN spacer layer and the AlGaN layer, the interface including a n-type delta doped GaN layer. The diode includes an anode formed on the first side. The diode includes a cathode formed on the second side.

In some embodiments, the anode includes a p-ohmic region adjacent the p+GaN layer. The cathode includes a n-ohmic region adjacent the pGaN layer, the UID GaN spacer layer, the n-type delta doped GaN layer, and the AlGaN layer.

In some embodiments, the n-ohmic region includes a metal 2D electron gas contact structure.

In some embodiments, a notch is formed in the pGaN layer.

In some embodiments, the notch is configured to reduce or eliminate hole conduction between the anode and cathode.

In some embodiments, the notch is between the cathode and the anode. The notch is closer to the cathode than the anode.

In some embodiments, the pGaN layer includes an upper surface and a lower surface. The notch comprises a column extending through the pGaN layer from the upper surface to the lower surface, and the column is a formation that is devoid of pGaN material.

In some embodiments, the diode includes a passivation layer.

Some embodiments relate to a transistor comprising two diodes, at least one diode being an embodiment of a diode disclosed herein.

Embodiments can relate to a two-dimensional electron gas (2DEG) channel for a super-heterojunction structure including: a n-type modulation doped layer; at least one p-type layer; and wherein the n-type modulation doped layer is adjacent the at least one p-type layer to generate a charge balanced super-heterojunction region.

In some embodiments, the n-type modulation doped layer is formed by any one or combination of: n-type barrier layer doping; and n-type δ-doping in the barrier layer; and n-type doping at an interface between the barrier layer and the at least one p-type layer; and n-type δ-doping at an interface between the barrier layer and the at least one p-type layer.

In some embodiments, the at least one p-type layer comprises at least two p-type layers; a first p-type layer comprises GaAs, GaN, or GaOₓ; a second p-type layer comprises AlGaAs, AlGaN, or AlGaOₓ.

In some embodiments, p-type dopant for the p-type layer comprises any one or combination of Mg, Li, Na, K, Be, Zn Ca, and Be.

Some embodiments relate to a diode comprising at least one 2DEG channel disclosed herein.

In some embodiments, the diode has a plurality of 2DEG channels.

Some embodiments relate to a transistor comprising at least one diode having a 2DEG channel disclosed herein.

Embodiments relate to a diode, comprising: a super-heterojunction structure having at least one two-dimensional electron gas (2DEG) channel. The at least one 2DEG channel comprising: a n-type modulation doped layer; at least one p-type layer; and wherein the n-type modulation doped layer is adjacent the at least one p-type layer to generate a charge balanced super-heterojunction region. The diode has an anode and a cathode.

In some embodiments, the anode is configured as a Schottky contact and a p-ohmic contact.

In some embodiments, the Schottky contact forms a Schottky contact between the anode and the at least one 2DEG channel.

In some embodiments, the p-ohmic contact forms an ohmic contact between an p-ohmic metal and the at least one p-type layer.

In some embodiments, a p+ layer formed between a p-ohmic metal and the at least one p-type layer.

In some embodiments, the Schottky contact and the p-ohmic contact are electrically connected.

In some embodiments, the cathode is configured as a n-ohmic contact.

In some embodiments, the n-ohmic contact forms an ohmic contact between the cathode and the at least one 2DEG channel.

In some embodiments, a notch configured to reduce or eliminate hole conduction between the anode and cathode.

In some embodiments, the notch is a void formed by etching or a region formed by plasma treatment.

Some embodiments relate to any of the diode disclosed herein, the diode comprising: a p-n junction comprising a p-type region and a n-type region; the anode in electrical connection with the p-type region; the cathode in electrical connection with the n-type region; and the anode is configured as a p-ohmic contact.

Embodiments relate to a diode, comprising: a super-heterojunction structure having a charge balance region. The charge balance region comprising: a passivation layer; a p-type layer adjacent the passivation layer; an unintentionally doped (UID) spacer layer adjacent the p-type layer; an UID barrier layer adjacent the UID spacer layer; a n-type modulation doped layer between the UID spacer layer and the UID barrier layer; an UID channel layer adjacent the UID barrier layer; and a buffer layer adjacent the UID channel layer. The diode includes an anode and a cathode.

In some embodiments, the anode is configured as a Schottky contact and a p-ohmic contact.

In some embodiments, the Schottky contact forms a Schottky contact between the anode and at least one two-dimensional electron gas channel.

In some embodiments, the p-ohmic contact forms an ohmic contact between a p-ohmic metal and the at least one p-type layer.

In some embodiments, a p+ layer formed between a p-ohmic metal and the at least one p-type layer.

In some embodiments, the Schottky contact and the p-ohmic contact are electrically connected.

In some embodiments, the cathode is configured as a n-ohmic contact.

In some embodiments, the n-ohmic contact forms a n-ohmic contact between the cathode and at least one two-dimensional electron gas channel.

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 is an exemplary schematic of an embodiment of a multi-channel Schottky barrier diode with a super-heterojunction structure.

FIG. 2 is a cross-section view of an exemplary multi-channel diode with a super-heterojunction structure.

FIG. 3 is a cross-section view of an exemplary single-channel diode with a super-heterojunction structure.

FIG. 4 is a graph showing dependence of specific on-resistance (Rₒₙ·A) and breakdown voltage (V_{B}) on n-type delta-doping density [N_{d,2-D}] for single-channel super-heterojunction Schottky diodes with different AlGaN layer thickness.

FIG. 5 is a graph showing dependence of Rₒₙ·A of single-channel super-heterojunction Schottky diodeson the p-type doping concentration [N_{a,3-D}].

FIG. 6 is a graph showing dependence of V_{B} single-channel super-heterojunction Schottky diodes on the p-type doping concentration [N_{a,3-D}].

FIG. 7 is a graph showing sensitivity of normalized V_{B} to doping imbalance [N_{d,2-D}−N_{a,2-D}].

FIG. 8 is a graph showing reverse I-V characteristics of charge-balanced GaN/AlGaN/GaN single-channel Schottky diodes with different anode-to-cathode spacing (L_{ac}).

FIG. 9 is a graph showing Rₒₙ·A and V_{B} characteristics as a function of L_{ac}.

FIG. 10 is a graph showing tradeoff relationship between R_{ON} A and V_{B} of charge-balanced single- and multi-channel super-heterojunction Schottky diodes designed for 0.35-22.5 kV applications.

FIG. 11A is a schematic of the anode voltage waveform setup for the simulation.

FIG. 11B is a simulated turn-off (between first ON-state and first OFF-state) transient switching waveforms of charge-balanced single-channel Schottky diode.

FIG. 11C is a simulated turn-on (between first OFF-state and second ON-state) transient switching waveforms of charge-balanced single-channel Schottky diode.

FIG. 12A is a schematic of band energy diagram at anode/p-GaN junction and simulated hole concentration contours in a first ON-state: Vₐ=2 V.

FIG. 12B is a schematic of band energy diagram at anode/p-GaN junction and simulated hole concentration contours in a first OFF-state: Vₐ=−2 kV.

FIG. 12C is a schematic of band energy diagram at anode/p-GaN junction and simulated hole concentration contours in a second ON-state: Vₐ=2V during the transient switching.

FIG. 13 is a schematics of single-channel SHJ Schottky diode with p-ohmic anode electrodes.

FIG. 14 is a graph showing simulated turn-off (between first ON-state and first OFF-state) ransient switching waveforms for SHJ Schottky diodes having p-ohmic anode electrode with different p-type ohmic contact resistivity values.

FIG. 15 is a graph showing turn-on (between first OFF-state and second ON-state) transient switching waveforms for SHJ Schottky diodes having p-ohmic anode electrode with different p-type ohmic contact resistivity values.

FIG. 16 is a graph showing a comparison of forward I-V characteristics of three different diode structures: solid line [SHJ-diode without p-anode electrodes (L_{ac}=20 μm)], dashed line [SHJ-diode without p-anode electrodes (L_{ac}=18 μm)], and dotted line [SHJ diode with p-anode electrodes (L_{ac}=20 μm, Lₚ=2 μm)].

FIG. 17 is a graph showing a comparison of reverse I-V characteristics of three different diode structures: solid line [SHJ-diode without p-anode electrodes (L_{ac}=20 μm)], dashed line [SHJ-diode without p-anode electrodes (L_{ac}=18 μm)], and dotted line [SHJ diode with p-anode electrodes (L_{ac}=20 μm, Lₚ=2 μm)].

FIG. 18 show a simulated 2-D lateral E-field contour of SHJ-diode with p-ohmic anode electrode [at Vₐ=−4 kV].

FIG. 19 shows a cutline 1-D lateral e-filed distribution with a different reverse bias.

FIG. 20 is a cross-section view of an exemplary diode with a super-heterojunction structure.

FIG. 21A shows a simulated conduction band diagrams at equilibrium with varying pGaN thickness.

FIG. 21B shows E-field profiles along with 2DEG at −1 kV for GaN SHJ-SBD with varying pGaN thickness.

FIG. 22 shows I-V characteristics of SHJ-SBDs with L_{SHJ}=17 μm and L_{SHJ}=37 μm measured before and after charge balance etching.

FIG. 23 shows C-V characteristics of SHJ-SBDs with L_{SHJ}=17 μm and L_{SHJ}=37 μm measured before and after charge balance etching.

FIG. 24 shows reverse I-V characteristics of a SHJ-SBD with L_{SHJ}=17 μm measured before and after the charge balance etch, as well as after the SU-8 passivation.

FIG. 25 shows breakdown characteristics of SHJ-SBDs after SU-8 passivation.

FIG. 26 is a schematic of dynamic switching measurement setup.

FIG. 27 shows voltage and current waveforms of L_{SHJ}=37 m SHJ-SBD at V_{R}=2.8 kV. The inset of the figure shows a zoomed-in view of the voltage waveform at the on-state

FIG. 28 shows dynamic/static on-resistance characteristics of L_{SHJ}=37 m GaN SHJ-SBD and benchmark with state-of-the-art results.

FIG. 29 shows process steps for GaN SHJ-SBDs: (a) Isolation, (b) deep trench etch for n-ohmic and Schottky contact, (c) n-ohmic formation, (d) p-ohmic formation, (e) Schottky contact and metal pad formation, (f) notch etching to cut off hole conduction path, (g) charge balance etch, (h) SU-8 passivation.

FIG. 30 shows a comparison of circular TLM I-V characteristics for an embodiment of the diode and prior art.

FIG. 31A shows cross-sectional schematics of GaN SHJ-PN diodes before notch etching.

FIG. 31B shows cross-sectional schematics of GaN SHJ-PN diodes after notch etching.

FIG. 31C shows I-V characteristics of GaN SHJ-PN diodes along with notch etching process.

FIG. 32A shows a cross-sectional schematic of exemplary isolation test structure.

FIG. 32B shows I-V characteristics of isolation test structures (isolation gap=20 μm), with dry etch only, dry etch plus low energy implantation, and dry etch plus high energy implantation.

FIG. 33 shows I-V characteristics of a fabricated GaN SHJ-SBDs with L_{AC} of 100 μm and device width of 100 μm.

FIG. 34 shows reverse I-V characteristics of the same three GaN SHJ-SBDs with measured at Pennsylvania State University and Naval Research Laboratory.

FIG. 35. Specific on-resistance (R_{ON,SP}) versus V_{B} benchmark of the GaN SHJ-SBDs against state-of-the-art lateral GaN SBDs.

FIG. 36 shows exemplary modulation doping techniques.

FIG. 37 shows how impurity charge balance between the n-type doped layer and p-type doped layers can be achieved via the super-heterojunction design.

FIG. 38 shows how use of a p-ohmic contact formation assists in the switching operations of the device.

FIG. 39 shows anode Schottky contact formation.

FIG. 40 shows cathode n-ohmic contact formation.

FIG. 41 shows notch formation via plasma treatment.

FIG. 42 shows a multi-channel super-heterojunction Schottky barrier diode design.

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

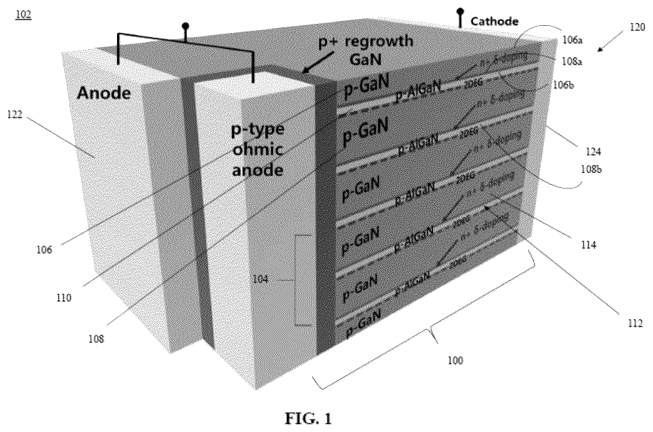

Referring to FIGS. 1-3, embodiments relate to a super-heterojunction structure 100. As will be discussed herein, the structure 100 can include a heterojunction (e.g., an interface that occurs between at least two layers of dissimilar crystalline structures) and can be used to form a diode 102. It is contemplated for the diode 102 to be a Schottky diode, in which the heterojunction comprises a semiconductor material and a metal.

It is further contemplated for the structure 100 to be a planar member with a rectangular or square cross-section from the top-down. However, the structure 100 can be of other cross-section shapes. The structure 100 can include a channel 104. The channel 104 provides balancing of charge between n-type modulation doping (e.g., delta-doping) and p-type layer. Specific embodiments discuss a GaN/AlGaN/GaN layer, but other channel 104 structures can be used, such as GaAs/AlGaAs/GaAs, GaOx/AlGaOx/GaOx, etc. With the exemplary embodiment shown in the figures, the channel 104 can include a p-doped upper GaN layer (upper p-GaN layer) 106, a p-doped lower GaN layer (lower p-GaN layer) 108, and a p-doped AlGaN layer (p-AlGaN layer) 110 between the upper p-GaN layer 106 and the lower p-GaN layer 108. The structure 100 can further include an interface 112 at the upper p-GaN layer 106 and the p-AlGaN layer 110. The interface 112 can include a n-type delta doped GaN layer (delta-nGaN layer) 114. Delta-doping is a doping technique to generate thin layers of high dopant concentration. An exemplary doping method for delta-doping can be a metal organic chemical vapor deposition (MOCVD) growth technique. It should be noted that delta-doping is discussed for exemplary purposes, and that it is not necessary to use delta-doping to provide the n-type modulation doping. Thus, the interface 112 can include a n-type modulation doped layer 114 (delta-doping just being one example of such). With the GaN/AlGaN/GaN structure, it can be a n-type modulation doped GaN layer 114.

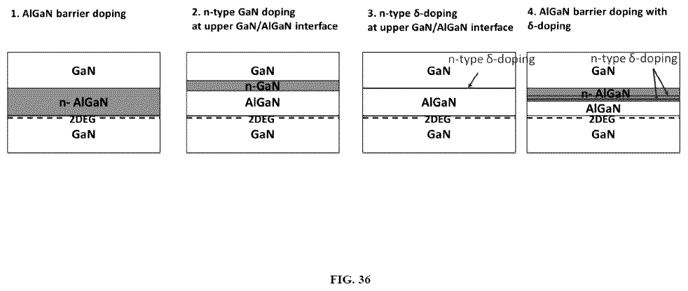

As can be appreciated from the above, the 2DEG channel 104 is generated by combination of n-type modulation doping layer 114 and AlGaN layer 110. N-type modulation doping layer 114 provides the free electrons, and the AlGaN layer 110 tilts band gap and transfers the electrons from the n-type modulation doping layer 114 to the 2DEG. N-type modulation doping between upper GaN/AlGaN interface 112 enables high doping density without degrading the material quality. Again, delta-doping is just one of the modulation doping methods. N-type barrier layer doping (e.g., n-type AlGaN barrier doping), n-type δ-doping in the barrier layer, (e.g., n-type δ-doping in the AlGaN barrier), n-type doping at an interface between the barrier layer and the at least one p-type layer (e.g., n-type GaN doping at the upper GaN/AlGaN interface), and n-type δ-doping at an interface between the barrier layer and the at least one p-type layer (e.g., AlGaN barrier doping with δ-doping) are other exemplary modulation doping methods that may be used in addition to, or in the alternative to, the n-type δ-doping at the upper GaN/AlGaN interface 112 discussed herein. (See FIG. 36). In a conventional single-channel AlGaN/GaN structure, polarization field tilts the energy band, resulting in the transfer of electrons from surface donors to the AlGaN/GaN heterojunction, forming a high-density 2DEG channel without any impurity doping. However, in multiple GaN/AlGaN/GaN structures, surface donors cannot contribute sufficient and equal amount of electrons to each 2DEG channel in a GaN/AlGaN/GaN structure where the 2DEG channel is far away from the surface. N-type doped layer (modulation doping) provides electrons needed by 2DEG channel 104 so as to generate a high density 2DEG (two-dimensional electron gas) channel 104 with AlGaN layer 110. This can be particularly useful with a multi-channel structures.

Using GaN/AlGaN/GaN and delta-doping as an example, the structure 100, from a top-down, can include an upper p-GaN layer 106 as the top layer. A delta-nGaN layer 114 can be the next layer (e.g., delta-nGaN layer 114 is adjacent the upper p-GaN layer 106. A p-AlGaN layer 110 can be the next layer (e.g., the p-AlGaN layer 110 is adjacent the delta-nGaN layer 114). A lower p-GaN layer 108 can be the next layer (e.g., the lower p-GaN layer 108 is adjacent the p-AlGaN layer 110. Any of the thicknesses of layers can be adjusted to meet a desired design criteria. Any of the doping concentrations of p-type dopants for any of the layers can be adjusted interface with to meet a desired design criteria. Any one or combination of layers can be configured to interface with the entire surface area of its adjacent layer, or only partially interface with the surface area of its adjacent layer.

The diode 102 can be a single channel diode 102 or a multi-channel diode 102. Thus, in some embodiments, the structure 100 can include a plurality of channels 104. For instance, the structure 100 can include an upper channel 104, at least one intermediate channel 104, and a lower channel 104. The structure 100 can be arranged such that, within the upper channel 104, its lower p-GaN layer 108 serves as an upper p-GaN layer 106 for an intermediate channel 104 adjacent the upper channel 104. Within the lower channel 104, its upper p-GaN layer 106 serves as a lower p-GaN layer 108 for an intermediate channel 104 adjacent the lower channel 104. Within any of the intermediate channels 104, the upper p-GaN layer 106 of an intermediate channel 104 serves as a lower p-GaN layer 108 for an adjacent intermediate channel 104, and the lower p-GaN layer 108 for an intermediate channel 104 serves as an upper p-GaN layer 106 for an adjacent intermediate channel 104.

For instance, suppose the structure 100 has an upper channel 104, an intermediate channel 104, and a lower channel 104. The upper channel 104 can include: an upper p-GaN layer 106; a delta-nGaN layer 114; a p-AlGaN layer 110; and a lower p-GaN layer 108. The intermediate channel 104 can include: an upper p-GaN layer 106 (which is the lower p-GaN layer 108 of the upper channel 104); a delta-nGaN layer 114; a p-AlGaN layer 110; and a lower p-GaN layer 108. The lower channel 104 can include: an upper p-GaN layer 106 (which is the lower p-GaN layer 108 of the intermediate channel 104); a delta-nGaN layer 114; a p-AlGaN layer 110; and a lower p-GaN layer 108.

In some embodiments, the structure 100 can be configured such that the plurality of channels 104 are arranged in a stack. The stack can be a vertical stack (e.g., from the top down the layer arrangement is upper channel 104, at least one intermediate channel 104, and lower channel 104) or a horizontal stack (e.g., from side to side the layer arrangement is upper channel 104, at least one intermediate channel 104, and lower channel 104). Assuming a vertical stack configuration, each upper p-GaN layer 106 has a top surface 106a and a bottom surface 106b, and a distance between the top and bottom surfaces 106a, 106b is a width (W) of the upper p-GaN layer 106. Each lower p-GaN layer 108 has a top surface 108a and a bottom surface 108b, and a distance between the top and bottom surfaces 108a, 108b is a width (W) of the lower p-GaN layer 108. In some embodiments, the upper p-GaN layer 106 of the upper channel 104 has a W<any of the W's of any upper or lower pGaN layers of any intermediate channel 104. Similarly, the lower p-GaN layer 108 of the lower channel 104 has a W<any of the W's of any upper or lower p-GaN layers of any intermediate channel 104. As will be discussed in detail later, this relative thick upper p-GaN layer 106 of the upper channel 104 and lower p-GaN layer 108 of the lower channel 104 allows for medium-low p-type doping, which is favorable for reducing impurity scattering and maintaining high 2DEG mobility.

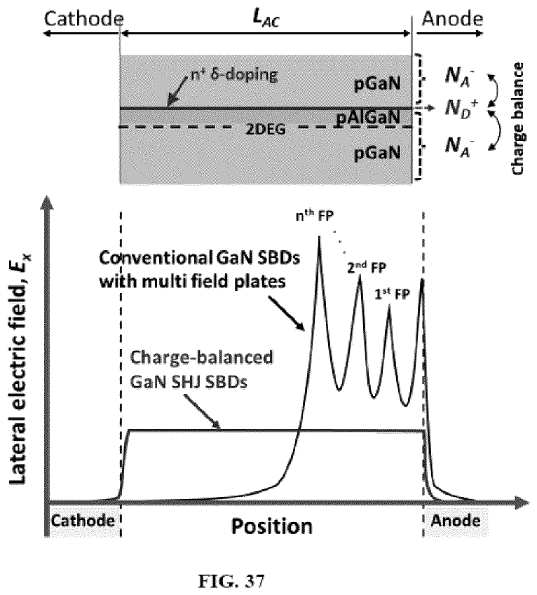

Referring to FIG. 37, impurity charge balance between n-type doped layer 114 and p-type doped layer (in other words, N_{D}⁺ and N_{A}⁻ have same amounts of charge) is a key aspect to the super-heterojunction design. The charge balance at the off-state creates a rectangular e-field shape along the device, resulting in extremely higher breakdown voltage. In this case, the following charge balance was conducted. For n-type (N_{D}⁺): n+ delta doping. For p-type (N_{D}⁺): upper pGaN+pAlGaN+lower pGaN. Relatively thick pGaN layers 106, 108 with medium-low p-doping concentration can be used for reducing impurity scattering and maintaining high 2DEG mobility. However, any charge-balance between n-type and p-type doping can be used for the super-heterojunction design.

With the exemplary embodiment shown, Mg is used as the p-type dopant for the upper p-GaN layer 106, the lower p-GaN layer 108, and/or the p-AlGaN layer 110; however, other p-type dopants can be used, such as Li, Na, K, Be, Zn Ca, Be, etc.

As noted herein, it is contemplated for embodiments of the structure 100 to be used to form a diode 102. For instance, the diode 102 can include a super-heterojunction structure 100. The structure 100 can include an upper channel 104, at least one intermediate channel 104, and a lower channel 104. Each of the upper channel 104, the at least one intermediate channel 104, and the lower channel 104 can include an upper p-GaN layer 106, a lower p-GaN layer 108, and a p-AlGaN layer 110 between the upper p-GaN layer 106 and the lower p-GaN layer 108. The structure 100 can further include an interface 112 at the upper p-GaN layer 106 and the p-AlGaN layer 110. The interface 112 can include a delta-nGaN layer 114. The upper channel 104, the at least one intermediate channel 104, and the lower channel 104 are can be arranged in a vertical stack having a first side 118 and a second side 120. An anode 122 can be formed on the first side 118. A cathode 124 formed on the second side 120.

The anode 122 can be configured as a Schottky contact and a p-ohmic contact (e.g., non-rectifying electrical junction forms between two conductors that exhibits a linear current-voltage (I-V) curve). In some embodiments, the p-ohmic contact is formed at each upper p-GaN layer 106 and lower p-GaN layer 108. For instance, the anode 122 can be formed to extend along the entire first side 118 such that a p-ohmic contact is generated for each upper p-GaN layer 106 and lower p-GaN layer 108 of the plural channels 104. In general, SHJ-SBD works well with two electrodes, positive (Schottky contact) and negative (n-ohmic) in DC conditions. The p-ohmic contact helps ensure proper switching by injecting a hole during the switching operation. Therefore, an additional p-ohmic contact can be formed and connected to the Schottky contact.

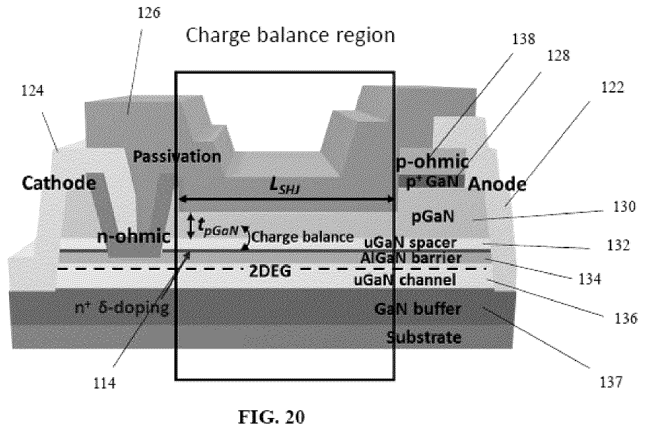

Some embodiments of the diode 102 can include a passivation layer 126 (see e.g., FIG. 20). It is contemplated for the passivation layer 126 to be formed on the exposed surfaces (surfaces exposed to the environment) of the diode 102; however, passivation layer(s) 126 can be formed on any surface or portion thereof. There can be any number of passivation layers 126. Any one or combination of passivation layers 126 can be the same or different from any other passivation layer 126. A passivation layer 126 can be formed by passivation of a surface layer (e.g., coating a surface of the diode 102 with a microcoating, deposition of an oxide layer or nitride layer, etc.). Passivation can be done to reduce or prevent corrosion, reacting with other materials, etc.

Embodiments of the diode 102 can be used to as a transistor. For instance, a transistor can include two diodes forming a three-terminal device which passes current from a high resistance region to a low resistance region. At least one diode of the two diodes can be embodiment of the diode 102 disclosed herein.

Referring to FIG. 20, some embodiments can include a diode having a super-heterojunction structure 100 comprising a stack of layers, the stack having a first side 118 and a second side 120. The stack can include a p+GaN layer 128, a pGaN layer 130 adjacent the p+GaN layer 128, an unintentionally doped (UID) GaN spacer layer 132 adjacent the pGaN layer 130, an AlGaN layer 134 adjacent the UID GaN spacer layer 132 an UID GaN channel layer 136 adjacent the AlGaN layer 134, and a GaN buffer layer 137 adjacent the UID GaN channel layer 136. The p+GaN layer 128 has a higher p-dopant concentration than that of the pGaN layer. The structure 100 can include an interface 112 at the UID GaN spacer layer 132 and the AlGaN layer 134. The interface 112 can include a n-type delta doped GaN layer 114. An anode 122 can be formed on the first side 118. A cathode 124 can be formed on the second side 120.

As noted above, one of the key operation principles of the inventive super-heterojunction structure is the charge balance between n-type modulation doping and p-type layer.

The embodiment in FIG. 20 is another structural configuration that can achieve this. FIG. 20 illustrates the charge balance region that leads to charge balance between n-type and p-type doping. The following characteristics provide additional detail as to the functions of the structural elements within the design of FIG. 20:
(1) n-type delta-doping: provides electrons to 2DEG.
(2) 2DEG channel is formed between AlGaN barrier and GaN channel.
(3) GaN buffer layer prevents unwanted leakage current path.
(4) p GaN: only use top pGaN for charge balance->challenge of activating buried pGaN.
(5) uGaN spacer: mitigate the unwanted downward diffusion of Mg from the pGaN.
(6) Charge balance between n⁺ δ-doping vs pGaN layer.
(7) p-type ohmic contact with p+GaN: ensures proper switching behaviors.

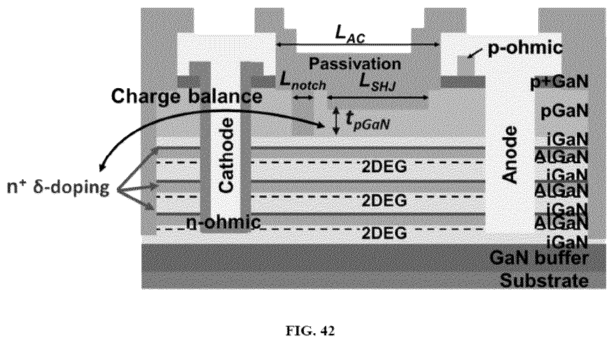

FIG. 20 shows a single channel super-heterojunction Schottky barrier diode design, and FIG. 42 shows a multi-channel super-heterojnuction Schottky barrier diode design. With the structure of FIG. 42 charge balance is conducted between multiple n+ delta doping and a single pGaN layer.

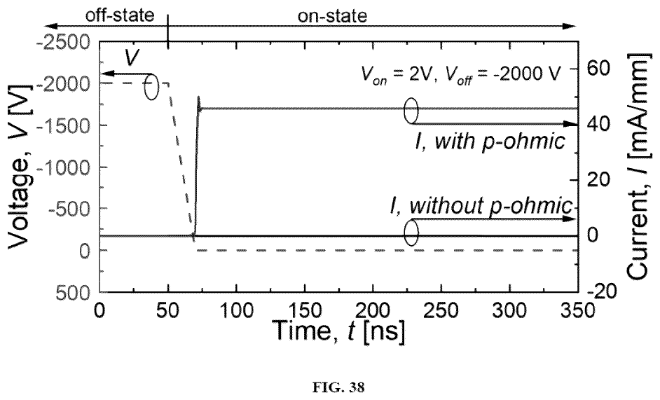

In some embodiments, the anode 122 can include a p-ohmic region 138 adjacent the p+GaN layer 128. The cathode 124 can include a n-ohmic region 140 adjacent the pGaN layer 130, the UID GaN spacer layer 132, the n-type delta doped GaN layer 114, and the AlGaN layer 134. The n-ohmic region 140 can be configured as a metal 2D electron gas contact structure. The ohmic formation on the pGaN is essential for the proper switching operation. P-ohmic contact 138 facilitates charging and discharging of holes. Without the pGaN ohmic contact 138, acceptors in the pGaN remain negatively charged during the on-state, depleting 2DEG and cannot be turned on. (See FIG. 38). In some embodiments, p⁺GaN layer can be added under the p-ohmic metal for better p-ohmic formation.

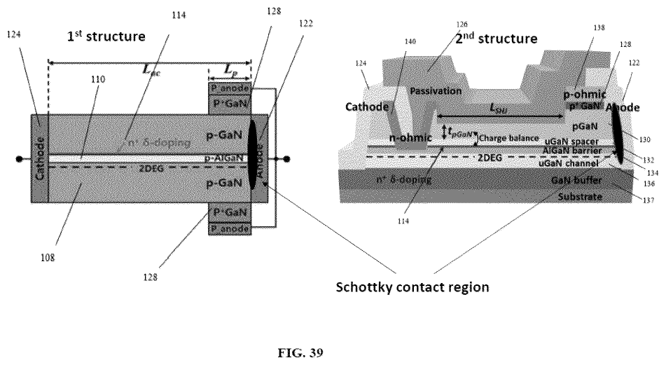

Referring to FIG. 39, anode 122 is an anode forming Schottky contact between a metal and a semiconductor. This Schottky contact controls rectifying the current of the diode 102 in Schottky barrier diode 102 design. Ni/Au, Mo/Au, W, etc. can be used to form the Schottky contact. Schottky metal is connected with p-ohmic (p-ohmic=p-type ohmic anode). The following characteristics provide additional detail as to the functions of the structural elements of the anode Schottky contact formation:
p-ohmic=p-type ohmic anode(p_anode).
p-ohmic does not directly control the diode but facilitates charging and discharging of holes to ensure the proper switching.
p+GaN layer can be added under the p-ohmic metal for better p-ohmic formation.
Pd/Au and Ni/Au, Pt, Cr/Au, and etc., various materials can be used for p-ohmic formation.

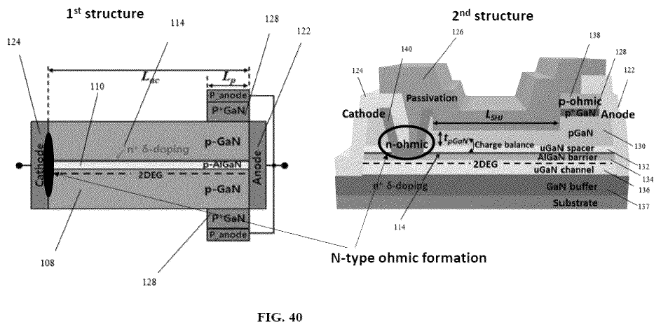

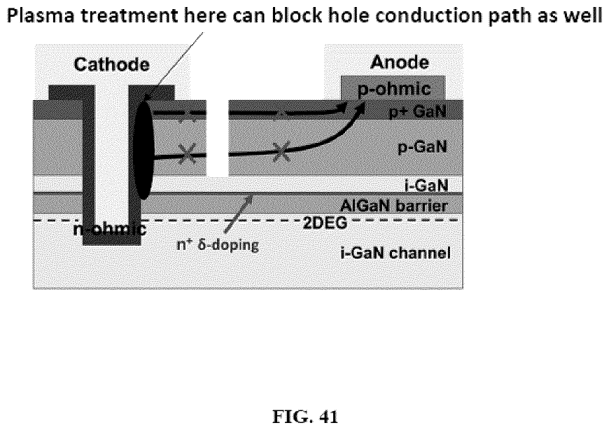

Referring to FIGS. 40, 124 and 140 is a cathode forming a n-ohmic contact. In the 1st structure (simulation design), 124 includes the n-ohmic contact (140). In the 2nd structure, the cathode is already formed by an n-ohmic step (140), but the n-ohmic metal is extended by cathode metal to form a probing pad. Ti/Al, Ti/Al/Ni/Au, Si/Ti/Al/Mo/Au, Ti/Al/Ti/Au, etc. metal stacks can be used for n-ohmic formation. It is understood that other metal stacks also can be used for n-ohmic formation.

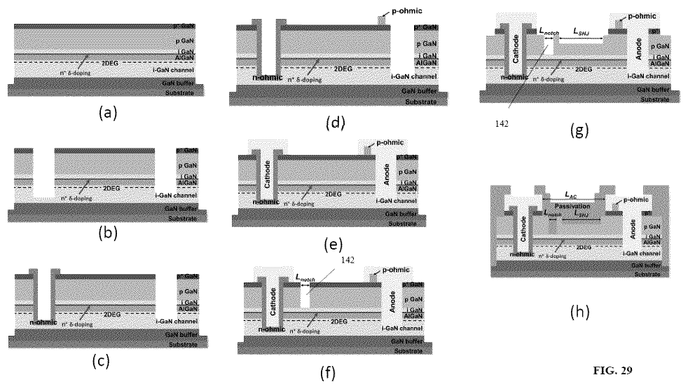

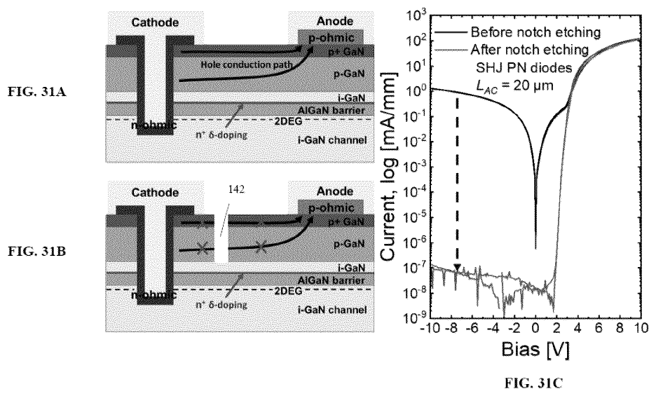

Referring to FIGS. 29 and 31, in some embodiments, a notch 142 can be formed in the pGaN layer 130. The notch 142 can be formed via etching. The notch 142 can be configured to reduce or eliminate hole conduction between the anode 122 and cathode 124. For instance, the notch 142 can be between the cathode 124 and the anode 122. The notch 142 may be formed to be closer to the cathode 124 than the anode 122. As can be appreciated from FIG. 29, the pGaN layer 130 includes an upper surface 130a and a lower surface 130b. The notch 142 can comprise a column extending through the pGaN layer 130 from the upper surface 130a to the lower surface 130b. The column can be a formation that is devoid of pGaN material. The notch 142 is configured to reduce or eliminate hole conduction between the anode 122 and the cathode 124. The notch 142 can be formed via etching, but also can be formed via plasma treatment (i.e., CF₄ treatment and/or Hydrogen plasma). With use of the notch 142, super-heterojunction PN diodes can be formed, wherein the anode is controlled by p-ohmic contact rather than Schottly contact.

Again, some embodiments of the diode 102 can include a passivation layer 126. As noted herein, it is contemplated for the diode 102 to be used as a transistor. The transistor can include two diodes, at least one diode being an embodiment of the diode 102 disclosed herein.

### Examples

The inventors conducted a systematic study on the design of an embodiment of a GaN/AlGaN/GaN super-heterojunction Schottky diode. Through physics-based TCAD simulation, three important design aspects are evaluated: 1) how to design a GaN/AlGaN/GaN structure to form a high-density 2-D electron gas and to scale it to multiple vertically stacked channels with less risk in reaching the critical thickness limited by the strain in epitaxy; 2) how to reach charge balance and how sensitive is the breakdown voltage with respect to the doping imbalance; and 3) how to ensure that the processes of depleting and accumulating electrons and holes in the structure are fast enough for practical power switching applications.

Over the past 10 years, advancements in GaN materials and devices have made GaN-based power devices a serious contender for power switching applications [1]. Meanwhile, the performance of Si-based power devices, especially the advanced superjunction MOSFETs, has also progressed significantly [2]. Combining the benefits of the wide bandgap GaN material and the advantages of the super-junction device design would lead to ultimate power switches with minimal power loss. Reported simulation performances show the great potential of GaN vertical superjunction for future power switching applications [3], [4]. A major challenge toward realizing the GaN vertical superjunction is to implement the p- and n-type pillars. For Si superjunction devices, this was done either by multiple epitaxial regrowth and implantation steps [5], or by a deep etch followed by sidewall epitaxial regrowth [6]. Regrowth of GaN epitaxy often resulted in unwanted impurities and defects at the regrowth interface [7], [8], causing difficulties in charge balance. Furthermore, when the defective regrowth interface is located in the high E-field region, a premature breakdown could occur. Ishida et al. reported the concept of natural superjunction based on polarization-induced 2-D electron gas (2DEG) and 2-D hole gas (2DHG) pairs in a single- and multichannel GaN/AlGaN/GaN heterostructures [9]. The lateral superjunction structure did not require any epitaxial regrowth.

In this study, the inventors discuss several key aspects in designing a GaN superjunction structure, through TCAD simulation of a GaN multichannel super-heterojunction (SHJ) Schottky diode, as shown in FIG. 1. The proposed new diode structure features include: 1) vertical stacking of multiple 2DEG channels to minimize ON-resistance; 2) balanced p- and n-type doping to achieve the maximum voltage blocking capability; and 3) p-type ohmic contact to ensure proper switching behaviors. Silvaco ATLAS was used for this study. Model parameters used in this study are listed in Table I.

TABLE I
MODELS AND PARAMETERS USED
FOR TCAD SIMULATION

| Physics | Model/parameter |
|---|---|
| Carrier statistics | Fermi-Dirac, incomplete ionization |
| Carrier transport | Drift-diffusion, |
| | concentration & field- |
| | dependent mobility [21] |
| Generation-recombination | Schokley-Read-Hall, Auger, and radiative |
| Breakdown | Selberherr impact ionization [22] |
| SRH lifetime | 0.1 ns for electron [23] 6.5 ns for hole [24] |
| Activation energy | 15 meV for donor 170 meV for acceptor |
| Radiative | 1.1 × 10⁻⁸ cm³/s [25] |
| recombination rate | |

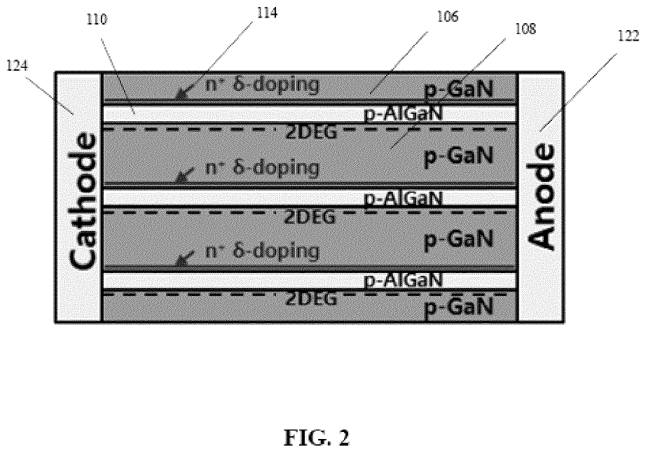

In a conventional single-channel AlGaN/GaN structure, polarization field tilts the energy band, resulting in the transfer of electrons from surface donors to the AlGaN/GaN heterojunction, forming a high-density 2DEG channel without the need for intentional impurity doping [10]. In order to build SHJ with multiple 2DEG channels as shown in FIG. 2 stacking of multiple GaN/AlGaN/GaN structures are needed. Since surface donors cannot contribute sufficient and equal amount of electrons to each 2DEG channel in a GaN/AlGaN/GaN structure where the 2DEG channel is far away from the surface, n-type delta-doping is often incorporated into the upper GaN/AlGaN interface to provide electrons needed by the 2DEG channel [11].

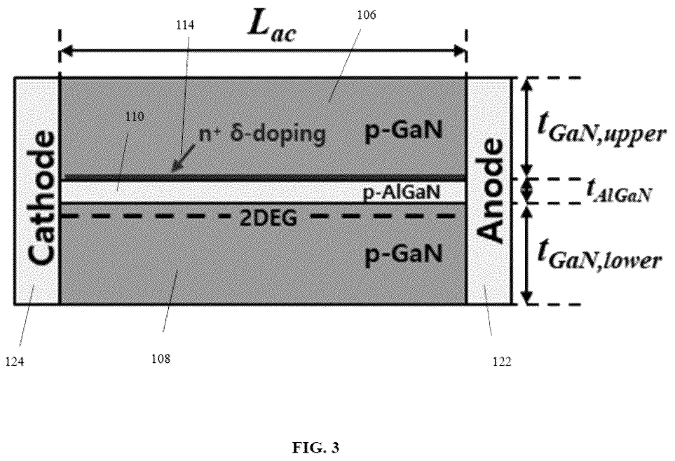

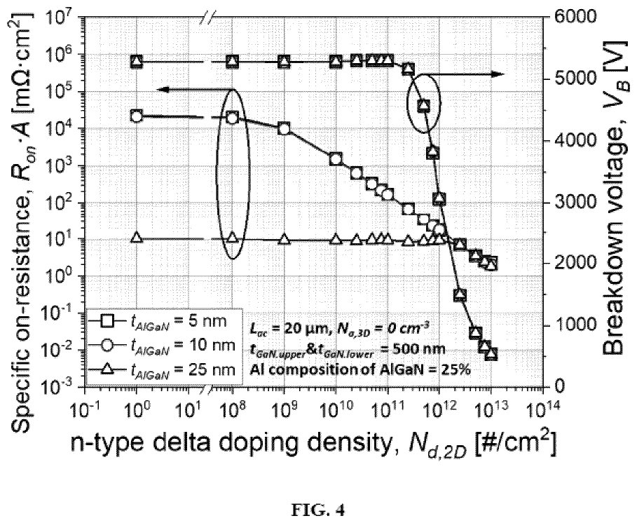

The inventors performed a TCAD simulation of single-channel GaN/AlGaN/GaN Schottky diode structures shown in FIG. 3. The anode-to-cathode spacing (L_{ac}) was kept at 20 μm. An AlGaN layer was sandwiched between two GaN layers, each having a thickness of 500 nm. The AlGaN layer had an Al composition of 25%. The AlGaN layer thickness (t_{AlGaN}) was varied from 5 to 25 nm. The n-type delta-doping density (N_{d,2-D}) was varied from 0 to 1×10¹³ cm⁻². Specific ON-resistance (R_{ON}·A) and breakdown voltage (V_{B}) were extracted from simulated forward and reverse I-V characteristics. FIG. 4 shows R_{ON}·A and V_{B} of the Schottky diode as a function of N_{d,2-D} and different t_{AlGaN}.

Structures with t_{AlGaN} of 5 and 10 nm behaved similarly. Their R_{ON}·A were as high as 2×10⁴ mΩ·cm² without sufficient amount of n-type delta-doping. This is because the polarization dipole across the AlGaN layer is not strong enough to transfer electrons from the surface states or the valance band of the upper GaN layer to form the 2DEG channel. Adding n-type delta-doping at the upper GaN/AlGaN interface effectively contributed electrons to the 2DEG channel, thereby lowering the R_{ON}·A down to 2.3 mΩ·cm² at delta-doping density of 1×10¹³ cm⁻². However, increasing delta-doping density also dramatically reduced the V_{B} from 5.3 kV to about 533 V. This was because under reverse bias, the added high density of donors became high density of positive fixed charges in the depletion region, resulting in high E-field. When the AlGaN layer thickness was increased to 25 nm, polarization dipole across the AlGaN layer became strong enough to transfer electrons from the valence band of the upper GaN layer to the conduction band of the lower GaN layer, forming 2DHG at the upper GaN/AlGaN interface and 2DEG at the lower AlGaN/GaN interface. Consequently, low R_{ON}·A of 10 mΩ·cm² can be achieved without the need for n-type doping. Adding n-type delta-doping to this structure further reduced the R_{ON}·A, but at the cost of decreasing V_{B}. Note that low R_{ON}·A and high V_{B} could be simultaneously achieved in this structure, when there was no n-type doping. This is because the 2DHG naturally balances the 2DEG, forming the so-called natural superjunction [9]. Practical implementation of the natural superjunction is limited by a few factors: 1) near valance trap states located at the upper GaN/AlGaN interface can affect the charge balance and the transient response [12]; 2) stacking multiple layers of thick AlGaN layer with large Al composition, which is needed to generate the 2DHG-2DEG pair, exceeds the critical thickness and causes film cracking [13], [14]; and 3) without p-type impurity doping, it is hard to form a p-type contacts to the 2DHG channel, which is needed to supply holes during switching as will be discussed later. In order to construct GaN/AlGaN/GaN SHJ structure with multiple 2DEG channels, a thin AlGaN layer with modest Al composition is preferred to avoid degradation of epitaxial material quality. With a thin AlGaN layer and modest Al composition, n-type doping is needed to form high-density 2DEG channels and achieve low R_{ON}·A. However, n-type doping disturbs the charge balance and requires additional measures to recover the V_{B}.

The degraded V_{B} can be recovered by adding p-type doping to balance the amount of positive and negative ionized impurities. In is SHJ structure, relatively thick upper (t_{GaN.upper}) and lower GaN layers (t_{GaN.lower}) are used so that only medium-low p-doping concentration is needed to balance the n-type delta-doping. The use of the medium-low p-type doping is favorable for reducing impurity scattering and maintaining high 2DEG mobility. Next, the inventors will discuss simulated forward, reverse, and transient characteristics of charge-balanced SHJ Schottky diodes. A 5-nm-thick AlGaN barrier layer with 25% Al composition was used in this study. Mg was used as the p-type dopant, with the activation energy of 170 meV.

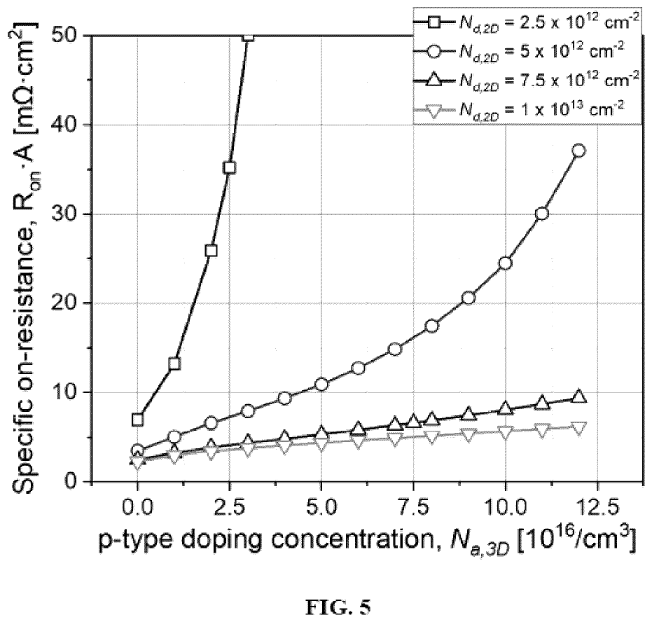

FIG. 5 shows the simulated R_{ON}·A as a function of 3-D p-type doping concentration (N_{a,3-D}) with a different n-type delta-doping density (N_{d,2-D}). Considering the difficulty in p-type modulation doping due to the Mg memory effect, uniform p-type doping for the upper GaN layer, the AlGaN layer, and the lower GaN layer is assumed. The N_{a,3-D} was varied from 0 to 1.2×10¹⁷ cm⁻³. Different N_{d,2-D} values of 2.5×10¹² cm⁻², 5×10¹² cm⁻², 7.5×10¹² cm⁻², and 1×10¹³ cm⁻³ were chosen for the simulation. For a given N_{d,2-D}, R_{ON}·A increased with increasing N_{a,3-D}, mainly due to depletion of electrons by the p-type doping. At charge balance condition, i.e., when N_{a,2-D} (the integration of N_{a,3-D} over the entire GaN/AlGaN/GaN thickness) equals N_{d,2-D}, the R_{ON}·A were 35.2 mΩ·cm² (N_{d,2-D}=2.5×10¹² cm⁻² and N_{a,3-D} 2.5×10¹⁶ cm⁻³), 10.9 mΩ·cm⁻² (N_{d,2-D}=5×10¹² cm⁻² and N_{a,3-D}=5×10¹⁶ cm³), 6.6 mΩ·cm² (N_{d,2-D}=7.5×10¹² cm⁻² and N_{a,3-D}=7.5×10¹⁶ cm⁻³), and 5.7 mΩ·cm⁻² (N_{d,2-D}=1×10¹³ cm⁻² and N_{a,3-D} 1×10¹⁷ cm⁻³), respectively. For a charge-balanced structure, as the doping level increases, the number of mobile carriers increases, resulting in lower R_{ON}·A.

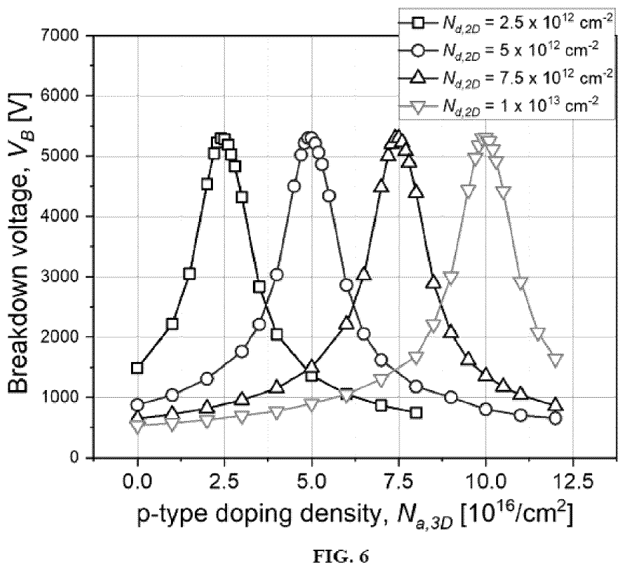

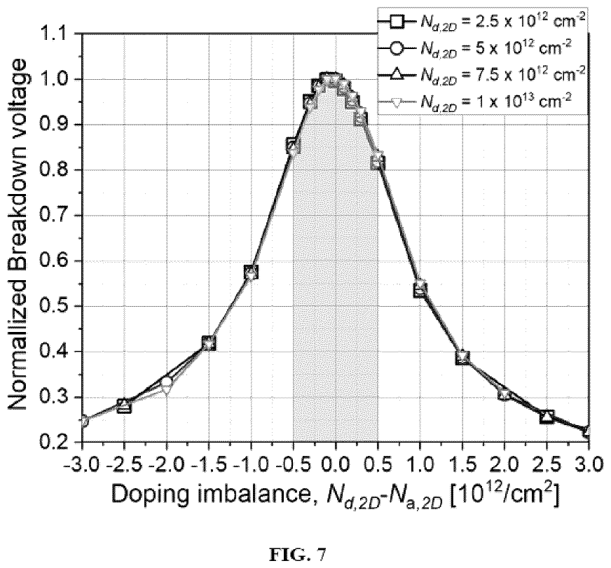

FIG. 6 shows the simulated V_{B} as a function N_{a,3-D}. Consistent with the superjunction theory, V_{B} reaches its maximum value at the charge balance condition. The maximum V_{B} value was 5.3 kV in this case, with anode-to-cathode spacing of 20 μm. Deviating from the charge balance point resulted in a rapid reduction of V_{B}. FIG. 7 shows the normalized breakdown voltage as a function of doping imbalance. About 80% of the maximum V_{B} can be maintained with up to 5×10¹¹ cm⁻² (in 2-D density), or 5×10¹⁵ cm⁻³ (in 3-D density), of doping imbalance.

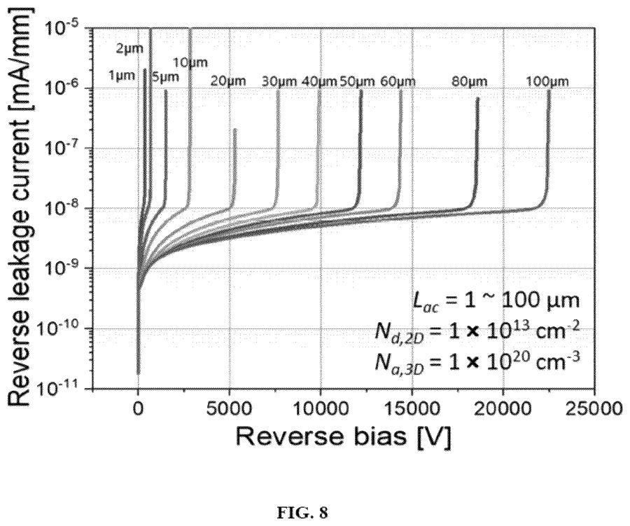

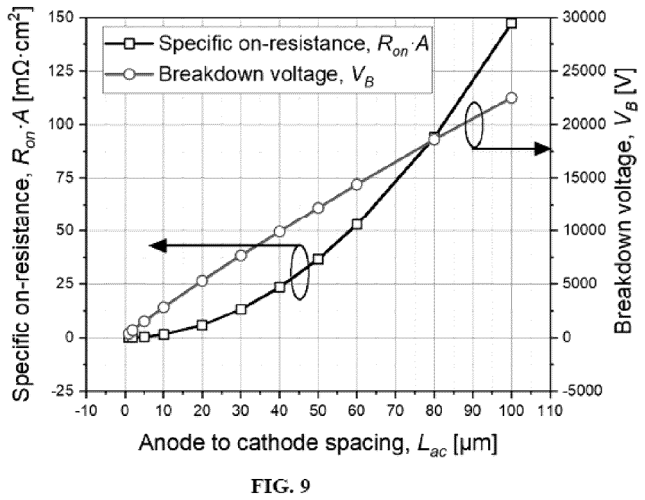

FIG. 8 shows the simulated reverse I-V characteristics of SHJ diodes with the L_{ac} varied from 1 to 100 μm. The simulated SHJ diodes had perfect charge balance, with N_{d,2-D}=1×10¹³ cm⁻² and N_{a,3-D} 1=10¹⁷ cm³. FIG. 9 summarizes the dependence of R_{ON}·A and V_{B} on the L_{ac}. The R_{ON}·A versus L_{ac} curve follows a parabolic relationship, as an increase in L_{ac} results in a proportional increase of both the R_{ON} and the A. The V_{B} versus L_{ac} curve follows a linear relationship and reaches 22.5 kV for L_{ac} 100 μm. The ability of scaling the V_{B} to more than 20 kV suggests this device structure a promising candidate for making medium voltage power switches.

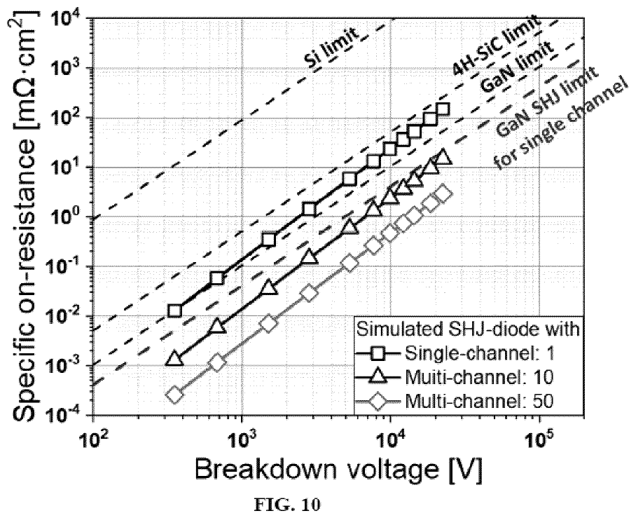

By stacking multiple GaN/AlGaN/GaN structures vertically, R_{ON}·A and V_{B} can be reduced while keeping the same V_{B}. FIG. 10 shows the tradeoff relationship between R_{ON}·A and V_{B} for SHJ Schottky diodes with different La, and number of channels. Theoretical 1-D unipolar limits for Si, SiC, and GaN materials and the GaN SHJ limit for single channel are shown on the same plot as references. With single-channel SHJ, the simulated performance of the diode is reaching the 1-D unipolar limit of GaN. By stacking multiple SHJ channels, the simulated device performance can far exceed that limit. For example, with ten channels, a 10-kV device can have a R_{ON}·A as low as 2.5 mΩ·cm², which is a factor of 20× better than the theoretical limit of conventional SiC MOSFETs and a factor of 50× better than the SiC MOSFET experimental performance results [15].

An analytical tradeoff relationship between R_{ON}·A and V_{B} for the GaN SHJ structure is derived. The derivation starts with a charge-balanced single-channel SHJ structure (p-GaN/delta-doped n-GaN/p-AlGaN/p-GaN). At OFF-state, the SHJ structure is fully depleted across the vertical pn heterojunction. In the charge-balanced structure (i.e., N_{d,2-D}=2N_{a,3-D}·t_{GaN}), the maximum E-field in the y-direction in GaN is given by

$${\vert {E}_{y} \vert}_{max , GaN} = \frac{q \cdot \frac{1}{2} \cdot {N}_{d , 2 - D}}{{ε}_{GaN}} = \frac{q \cdot {N}_{a , 3 - D} \cdot {t}_{GaN}}{{ε}_{GaN}} . \qquad ( 1.1 )$$

In the y-direction AlGaN is given by

$${\vert {E}_{y} \vert}_{max , AlGaN} = \frac{q \cdot {N}_{a , 3 - D} \cdot {t}_{GaN}}{{ε}_{GaN}} - \frac{( {σ}_{AlGaN} - {σ}_{GaN} )}{{ε}_{AlGaN}} . \qquad ( 1.2 )$$

q, ε_{GaN}, ε_{AlGaN}, σ_{GaN}, and σ_{AlGaN} are unit charge, permittivity, and polarization charge of GaN and AlGaN, respectively. In (1.2), the polarization E-field term “(σ_{AlGaN} σ_{GaN})/ε_{AlGaN}” is determined by the Al composition. It has an opposite direction from the E-field induced by the pn heterojunction space charges. Although the maximum E-field “|E_{y}|max=(E_{x·max}²+E_{y·max}²)^{1/2}” in AlGaN could be higher than |E|ₘₐₓ in GaN, AlGaN has a much higher critical field E_{c.AlGaN} than E_{c.GaN}. The calculation suggests that breakdown will always occur in the GaN. When |E♂ₘₐₓ in GaN reaches the E_{C.GaN}, the y component of the maximum E-field can be expressed as a faction of the E_{C.GaN}, given by

$${\vert {E}_{y} \vert}_{max} = \frac{q \cdot \frac{1}{2} \cdot {N}_{d , 2 - D}}{{ε}_{GaN}} = \frac{q \cdot {N}_{a , 3 - D} \cdot {t}_{GaN}}{{ε}_{GaN}} = α \cdot {E}_{C , GaN} . \qquad ( 2 )$$

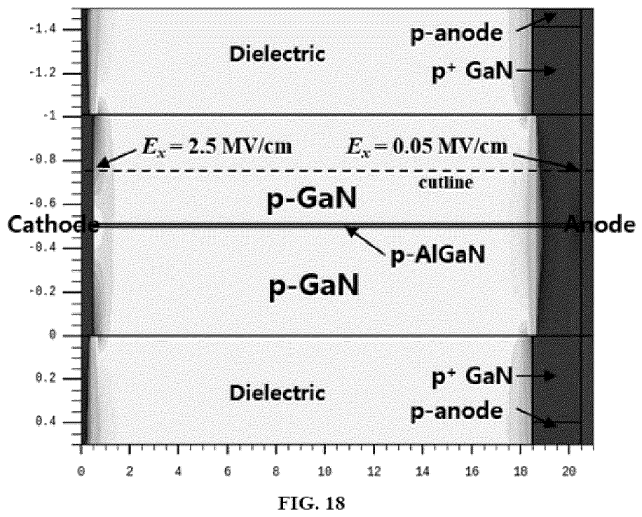

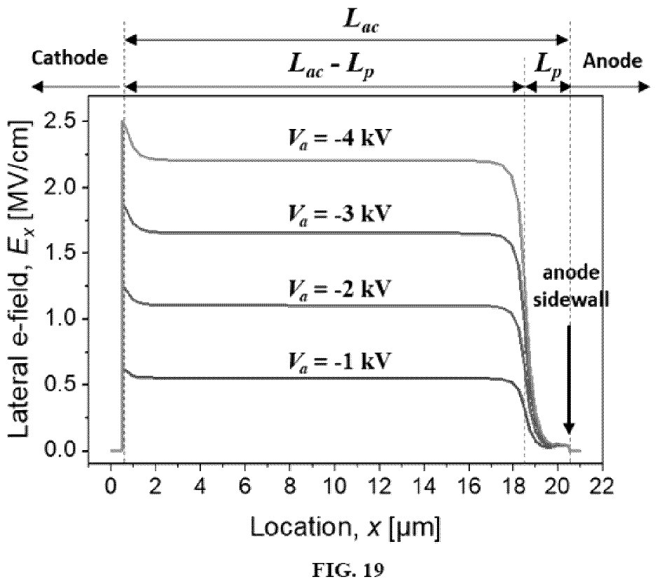

α is a factor with its value between 0 and 1. With the superjunction design, the lateral E-field (Eₓ) at OFF-state is approximately a constant value between the cathode and the anode as confirmed later by simulation results shown in FIGS. 18-19. When the device reaches its breakdown voltage, the Eₓ can be written as

V_{B}=|Eₓ|ₘₐₓ·L_{AC}=β·E_{C}·L_{AC} (3.1)

β is the factor with its value between 0 and 1. Factors α and β are related to each other through

α²+β²=1. (3.2)

When the device is in thermal equilibrium, from the charge neutrality equation, the density of the 2DEG is given by the difference of positive charge density (i.e., delta-doping density) and the negative charge density (i.e., acceptor density in the depletion region integrated over the depletion width)

nₛ=N_{d,2-D}−2·N_{a,3-D}·ω_{D} (4)

w_{D} is the depletion width of vertical p-n heterojunction in thermal equilibrium. Since n-type doping volume density is much higher than the p-type doping density, the p-n junction can be treated as one-sided. The w_{D} can be written as

$${w}_{D} = \sqrt{\frac{2 \cdot {V}_{bi} \cdot {ε}_{GaN}}{q \cdot {N}_{a , 3 - D}} .} \qquad ( 5 )$$

The R_{ON}·A of the single-channel SHJ structure can be expressed as

$$\begin{matrix}{R}_{ON} \cdot A = {R}_{s} \cdot \frac{{L}_{a c}}{{W}_{ch}} ( {L}_{a c} \cdot {W}_{ch} ) = \frac{1}{q \cdot {n}_{s} \cdot {μ}_{s}} {L}_{a c}^{2} \\ = \frac{1}{q ( {N}_{d , 2 - D} - 2 \cdot {N}_{a , 3 - D} \cdot {w}_{D} ) {μ}_{s}} {L}_{a c}^{2}\end{matrix} . \qquad ( 6 )$$

Rₛ, μₛ, and W_{ch} are sheet resistance of 2DEG, sheet mobility of 2DEG, and 2DEG channel width (i.e., dimension in z-direction). Substituting (2), (3.1), (3.2), and (5) into (6) and considering the stacking of multiple 2DEG channels, the R_{ON}·A for the multichannel GaN SHJ structure can be derived by

$${R}_{ON} \cdot A = \frac{1}{2 α ( 1 - {a}^{2} )} \frac{1}{{n}_{ch}} \frac{{V}_{B}^{2}}{( 1 - \sqrt{\frac{2 {V}_{bi}}{α \cdot {E}_{c , GaN} \cdot {t}_{GaN}}} ) {μ}_{s} \cdot {ε}_{GaN} \cdot {E}_{C , GaN}^{3}} \qquad ( 7 )$$

n_{ch} is the number of 2DEG channels. From (7), a large p-GaN thickness t_{GaN} is preferred to minimize the ON-resistance, without sacrificing anything else. The ideal specific ON-resistance of SHJ structure as a function of V_{B} are derived, whereas R_{ON}·A has a minimum value by optimizing the value of the a factor

$${R}_{ON} \cdot A = \frac{3 \sqrt{3}}{4} \frac{1}{{n}_{ch}} \frac{{V}_{B}^{2}}{{μ}_{s} \cdot {ε}_{GaN} \cdot {E}_{C , GaN}^{3}} , when a = \sqrt{\frac{1}{3}} . \qquad ( 8 )$$

With the α factor at its optimum value, from (2) is can be found that the optimum n-typing doping density N_{d,2-D}=1.9×10¹³ cm⁻². High N_{d,2-D} would require a thick AlGaN with high Al composition to transfer the electrons from the doped region to the 2DEG channel, at the risk of exceeding the critical thickness of the AlGaN. In this study, a conserative N_{d,2-D} value of 1×10¹³ cm⁻² was used.

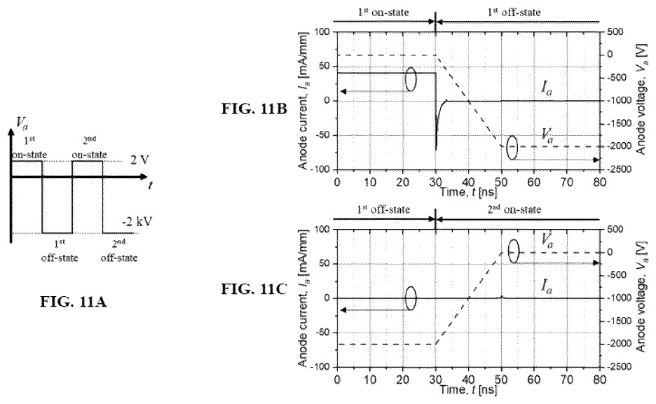

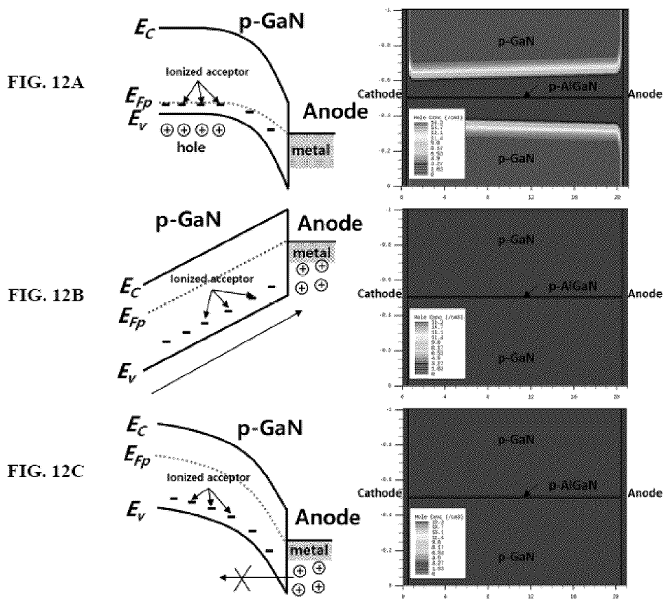

FIG. 11A is a schematic of the anode voltage waveform setup for the simulation. FIG. 11B is a simulated turn-off (between first ON-state and first OFF-state). FIG. 11C is turn-on (between first OFF-state and second ON-state) transient switching waveforms of charge-balanced single-channel SHJ Schottky diode. FIG. 12A is a schematic of band energy diagram at anode/p-GaN junction and simulated hole concentration contours in a first ON-state: Vₐ=2 V. FIG. 12B is a schematic of band energy diagram at anode/p-GaN junction and simulated hole concentration contours in a first OFF-state: Vₐ=−2 kV. FIG. 12C is a schematic of band energy diagram at anode/p-GaN junction and simulated hole concentration contours in a second ON-state: Vₐ=2V during the transient switching.

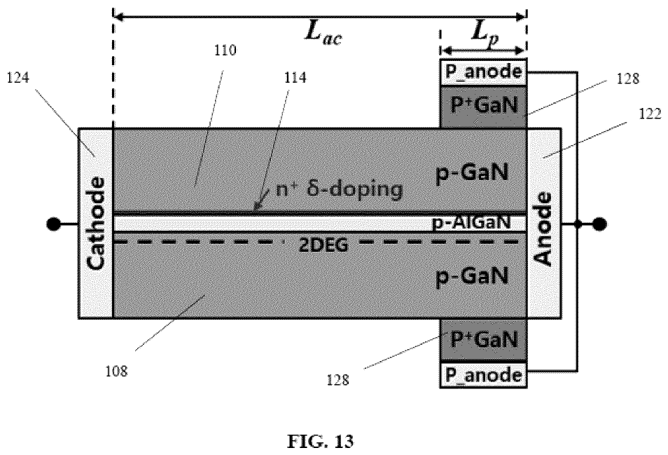

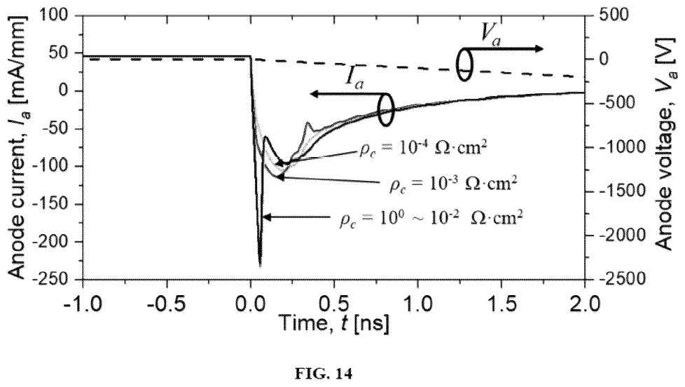

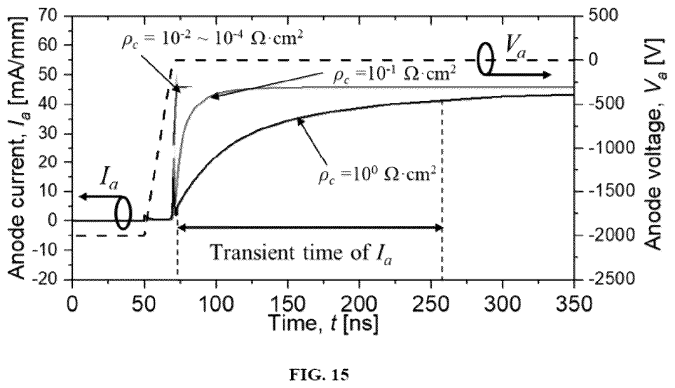

FIG. 13 is a schematics of single-channel SHJ Schottky diode with p-ohmic anode electrodes. FIG. 14 is a graph showing simulated turn-off (between first ON-state and first OFF-state). FIG. 15 is a graph showing turn-on (between first OFF-state and second ON-state) transient switching waveforms for SHJ Schottky diodes having p-ohmic anode electrode with different p-type ohmic contact resistivity values.

A transient switching simulation was performed to evaluate the dynamic performance of the proposed SHJ diode. The SHJ diode used for transient simulation was a single-channel GaN/AlGaN/GaN SHJ, where L_{ac}, t_{AlGaN}, N_{d,2-D}, and N_{a,3-D} were 20 μm, 5 nm, 1×10¹³ cm⁻², and 1×10¹⁷ cm⁻³, respectively. This structure yielded a simulated avalanche breakdown voltage of 5.3 kV. FIG. 11A shows a schematic of the anode voltage waveform used for the simulation. The switching frequency, duty ratio, and switching transient time were 1 MHz, 50%, and 20 ns (100 V/ns), respectively. The forward and reverse biases for the transient switching were 2 V and −2 kV. FIGS. 11B and 11C show the simulated turn-off (between first ON-state and first OFF-state) and turn-on (between first OFF-state and second ON-state) transient switching waveforms of the SHJ diode. The forward current of the SHJ diode was 43 mA/mm in the first ON-state, consistent with the static forward current. During the on-to-off transition, a negative current spike appeared corresponding to the reverse recovery process. During the off-to-on transition, the diode could not be turned on, with a forward current value as low as 5 μA/mm.

The inability of switching the diode from OFF-state to ON-state is due to the difficulty in supplying holes to the SHJ. To explain the mechanism, band diagrams were illustrated at the anode/p-GaN junction and hole concentration contours of the SHJ diode were simulated in FIGS. 12A-12C. During the first ON-state [FIG. 12A, Vₐ 2 V], there were large amounts of electrons and holes in the structure. The electrons provided a forward conduction path. Once the SHJ diode was reverse biased [FIG. 12B, Vₐ−2 kV], all holes in the p-type region were depleted out through the anode by the E-field, leaving behind negatively charged acceptors. Similarly, all electrons in the system were depleted out through the cathode, leaving behind positively charged donors. The charge balance between ionized acceptors and donors is the key to superjunction operation. When the diode was switched from the first OFF-state to the second ON-state [FIG. 12C, Vₐ 2 V], the supply of holes from the anode back into the p-type region was blocked by the Schottky barrier between the anode and the semi-conductor. The p-type region remained negatively charged, preventing the supply of electrons from the cathode back into the semiconductor. From this analysis, the SHJ concept is not able to switch without a proper p-type contact made to the structure to supply holes.

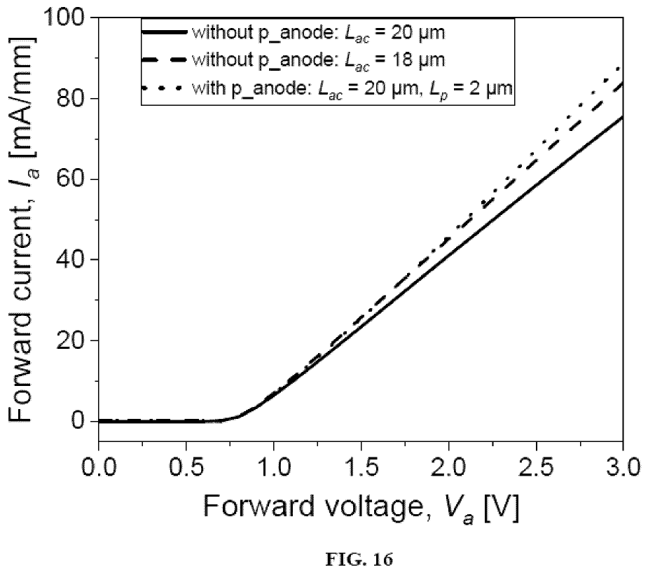

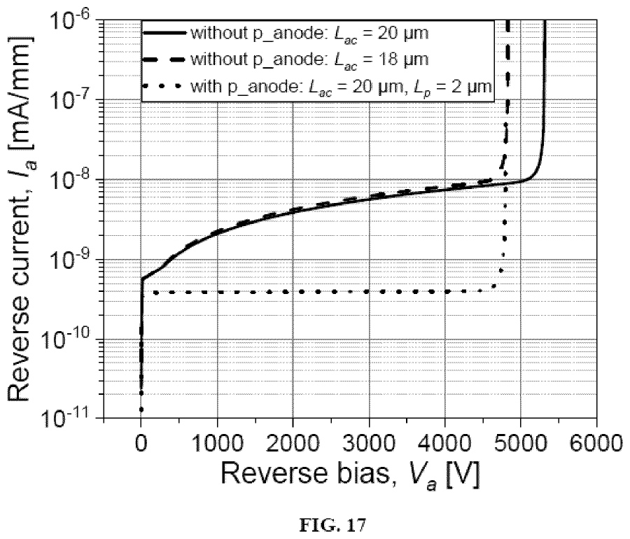

The serious switching problem can be solved by adding a p-type ohmic anode electrode. Through the p-type ohmic anode electrode, holes can be injected back into the semiconductor during the off-to-on switching transient. Injected holes neutralize the acceptors, thereby allowing electrons to be supplied to the semiconductor through the cathode, forming forward current conduction channel. It is important that p-type ohmic contacts are formed to all p-GaN layers, as shown in FIG. 1. Only adding p-type ohmic contact to the top p-GaN layer will fail to supply holes to the lower p-GaN layers separated by the 2DEG, even under a large forward bias. This is because the short minority carrier lifetime makes it extremely hard for the injected holes to diffuse across the n-type region. Using a simplified structure shown in FIG. 13, the impact of a p-type ohmic anode on device characteristics through 2-D simulation was evaluated. L_{ac} and length of the p-anode region were 20 and 2 μm, respectively. The anode and the p-anode are electrically connected. Other structural parameters are the same as those used in the previous transient simulation. Simulated switching waveforms shown in FIGS. 14-15 suggest that problem in off-to-on switching was fixed by adding the p-type ohmic contacts. Contact resistivity of the p-type ohmic contacts affects the turn-on time. For a p-type ohmic contact resistivity of 1×10⁻⁷˜1 Ω·cm², turn-on time of the anode current rising from 10% to 90% was 0.1-210 ns, sufficient for most of the power electronics applications. In practice, p-type ohmic resistivity ranging from 1×10⁻⁶ Ω·cm² to 1×10⁻⁴ Ω·cm² can be routinely achieved on as-grown p-GaN surface [16]. However, forming p-type ohmic contacts on the etched surface has been very challenging, due to the formation of donor-like nitrogen vacancies caused by plasma damage [17], [18]. Regrowth of p+-GaN on the etched p-GaN sidewall is needed to form p-type ohmic contacts [19] to all p-GaN layers in the multichannel SHJ structure. As the p-anode electrode was added, the “effective L_{ac}” (L_{ac} Lₚ) of the SHJ diode decreased by Lₚ. The forward current improved with the addition of the p-type ohmic anode as shown in FIG. 16. The improvement of forward current was due to the combined effects of a shorter effective La, and conductivity modulation provided by the forward-biased p-n junction. With the addition of the p-type ohmic anode electrodes, the V_{B} decreased slightly, consistent with the reduction of the effective L_{ac}, as shown in FIG. 17. Meanwhile, the leakage current was substantially reduced as compared with the structure without the p-type ohmic contacts. The low and flat reverse leakage characteristics can be explained by the E-field distribution. FIG. 18 shows the lateral E-field contour of SHJ diode with p-anode structure at Vₐ=4 kV. The p-anode electrodes clamped the lateral E-field at the Schottky junction at a very low value 0.05 MV/cm, as compared with the high value of 2.5 MV/cm in the device without the p-anodes. Drastic reduction of E-field at the Schottky junction resulted in a large reduction of thermionic field emission current, which is the dominating reverse leakage current mechanism [20]. FIG. 19 shows a 1-D lateral cutline of simulated E-field distribution with different reverse biases. The E-field was about constant along the effective L_{ac} direction and decreased rapidly under the p-anodes. The average E-field of the device increases linearly with the increase in the reverse voltage.

During the study, key design aspects of GaN multi-channel SHJ were evaluated. With n-type doping, high-density 2DEG can be formed in each channel of the GaN/AlGaN/GaN multichannel structure without the need for using the AlGaN layer with a high Al composition or large thickness, making it easier to scale to a larger number of channels before reaching the critical thickness. p-type doping is needed to balance the n-type doping and achieve the maximum V_{B}. p-type ohmic contacts to each p-type GaN layer is needed to ensure proper switching behaviors. The resulting GaN/AlGaN/GaN multichannel SHJ has the potential to well exceed the 1-D unipolar performance limit of SiC and GaN. While the work described for this study was based on a diode structure, the conclusions are applicable to transistor structures as well.

The next study relates to an experimental demonstration of charge-balanced GaN super-heterojunction Schottky barrier diodes (SHJ-SBDs). Charge balance between the n-type delta-doping and the p-type doping was achieved by adjusting the thickness of the pGaN. This device structure enabled scaling of breakdown voltage to over 3 kV, and dynamic switching up to 2.8 kV without using any field-plate.

GaN power switches have demonstrated performance benefits up to a 1.2 kV voltage rating [26], [27]. Scaling GaN power devices to higher voltages will bring benefits to high power systems, such as the electrical grid. For lateral GaN devices, blocking voltage can be increased by expanding the spacing between the gate and the drain for the transistor [28], and the cathode and the anode for the diode [29], [30]. At the off-state, surface and bulk trapping extend electron depletion to the spacing region, supporting a large potential drop. However, trapping-assisted depletion causes problems, such as, current collapse or dynamic on-resistance [31]. Current collapse can be mitigated by the multiple-field-plate structure [32]. However, scaling to a higher blocking voltage requires more field-plates, increased fabrication complexity, and less efficient utilization of the active area.

For vertical GaN devices, blocking voltage can be increased by enlarging the GaN drift layer thickness while simultaneously decreasing the doping density. Realizing such a thick lightly doped GaN drift layer requires challenging growth conditions and extremely long growth time [33]. Vertical GaN PN diodes with 4˜5 kV blocking voltage have been demonstrated [34], [35]. The feasibility of scaling the GaN drift layer thickness to support 10 kV or above remains uncertain.

A GaN super-heterojunction (SHJ) structure that leverages polarization effects can form a rectangular-shaped E-field, thereby, facilitating an increase of the blocking voltage [29], [36], [37]. The previous TCAD simulation study has suggested that p- and n-type doping were important for achieving a charge-balanced SHJ with favorable switching characteristics [38]. This study reports an experimental demonstration of the GaN SHJ Schottky barrier diode (SBD) discussed above. As shown in FIG. 20, the experimental device implemented three important designs suggested by the previous study: (1) n-type delta-doping at the upper GaN/AlGaN interface provides electrons needed by the 2DEG channel; (2) p-type GaN forms a charge-balanced super junction with the n-type delta-doping; (3) an ohmic contact to the pGaN facilitates charging and discharging of holes with fast response.

During this study, there were two modifications to the structure of the device discussed above that were made to ease device fabrication. First, p-type doping below the 2DEG channel was eliminated to circumvent the challenge of activating buried pGaN. Second, an undoped GaN spacer was added between the pGaN and the AlGaN barrier to mitigate the unwanted downward diffusion of Mg into the 2DEG channel.

The fabricated SHJ-SBDs exhibited scaling of blocking voltage over 3 kV. Dynamic switching measurements were performed up to 2.8 kV off-state bias, showing dynamic on-resistance degradation of 16% at 600V, 30% at 1 kV, and 59% at 2.8 kV. These results compare favorably with the reported values of ˜40% at 575 V [39], ˜2.5% at 650V [40], and 50% at 850V [41].

The epitaxial structure used for device fabrication was grown at Enkris by MOCVD on a sapphire substrate. From top to bottom, it consists of a 20 nm p+GaN layer, a 250 nm pGaN layer, a 70 nm unintentionally doped (UID) GaN spacer layer, a 10 nm Al_{0.25}Ga_{0.75}N barrier, a 300 nm UID GaN channel layer, and a GaN buffer layer. By introducing SiH₄ flow, Si delta-doping with a density of 7.5×10¹² cm⁻² was incorporated at the interface between UID GaN spacer and AlGaN barrier. Doping for the p+GaN and pGaN layers were realized by introducing Cp₂Mg flow, resulting in Mg densities of 1.5×10²⁰ cm⁻³ and 5×10¹⁷ cm⁻³, respectively. Lehighton contactless measurement performed after the epitaxial growth yielded a sheet resistance of 1236 Ω/sq. The Mg doping was activated by thermal annealing at 800° C. for 20 minutes in N₂ ambient.

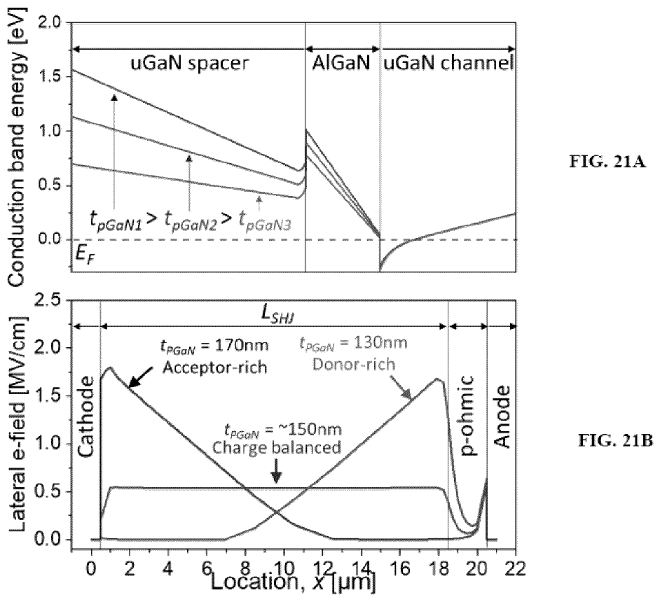

The strategy for approaching charge balance was to adjust the pGaN thickness by dry etching the epitaxy with a fixed doping design. TCAD simulation was performed to evaluate the impact of varying pGaN thickness. It was found that thicker pGaN caused an upward shift of conduction band edge, resulting in a slight decrease of 2DEG density, as shown in FIG. 21A. As pGaN thickness was increased, the SHJ-SBD transitioned from being donor-rich to acceptor-rich. This transition resulted in the shift of the peak E-field from the anode side to the cathode side, as shown in FIG. 21B. At the charge balanced condition, a rectangular shaped E-field can be observed with the lowest E-field peak.

The device fabrication started with formation of Ni/Au p-ohmic contacts, with self-aligned etch of the p+GaN layer outside the p-ohmic region by Cl₂/BCl₃-based inductively coupled plasma reactive ion etching (ICP-RIE) at a low chuck power of 15 W. The low power etch recipe resulted in a smooth etched surface with typical RMS roughness of less than 0.2 nm. Annealing the p-ohmic at 550° C. for 1 minute in air ambient yielded a contact resistance of 460 Ω·mm, or a specific contact resistance of 2.43×10⁻³ Ω·cm⁻². For n-ohmic formation, the top pGaN and UID GaN spacer layer were recessed by Cl₂/BCl₃-based non-selective etching followed by BCl₃/SF₆-based selective etching [42]. The n-ohmic was formed using Ti/Al/Ni/Au metallization followed by annealing at 870° C. for 30 sec in N₂ ambient. The contact resistance was 7.5 ohm-mm, or 3.7×10⁻³ Ω·cm⁻². The higher than typical contact resistance value is attributed to under etching during the n-ohmic recess process. Mesa isolation was formed by dry etching ˜600 nm of epi. TMAH treatment at 85° C. for 30 min was conducted to heal plasma etching damage [43]. Ni/Au metal stack was evaporated to form the Schottky contact and the pad metal. For the charge balance between p- and n-type doping, one or more runs of low power ICP-RIE etches were performed, targeting ˜20 nm reduction of the pGaN thickness for each run. Lastly, the devices were passivated using 5-μm-thick SU-8.

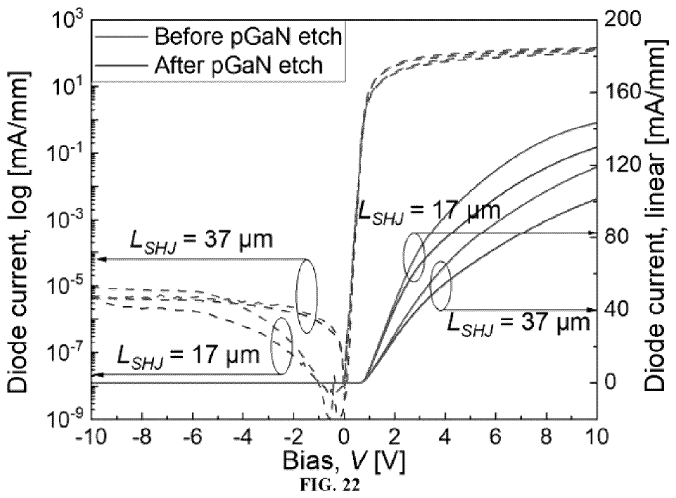

FIG. 22 shows I-V characteristics of the same GaN SHJ-SBDs measured before and after the charge balance pGaN etch. The diodes demonstrated well-defined rectifying behaviors, with on/off current ratios of 10⁷. The forward turn-on voltage extracted at a forward current of 1 mA/mm was around 0.7 V, typical for metal-2DEG sidewall Schottky contacts [44], [45]. At 2 V forward bias, the differential on-resistance measured before and after the pGaN etching was 32.6 Ω·mm and 29.1 Ω·mm for the 17 μm L_{SHJ} device, 50.5 Ω·mm and 43.77 Ω·mm for the 37 μm L_{SHJ} device. The difference in on-resistance between the two L_{SHJ} values yields a drift region sheet resistance of 1015 Ω/sq and 815 Ω/sq before and after the pGaN etching. The decrease of sheet resistance can be attributed to the reduction of negatively charged acceptors in the structure by the pGaN etching.

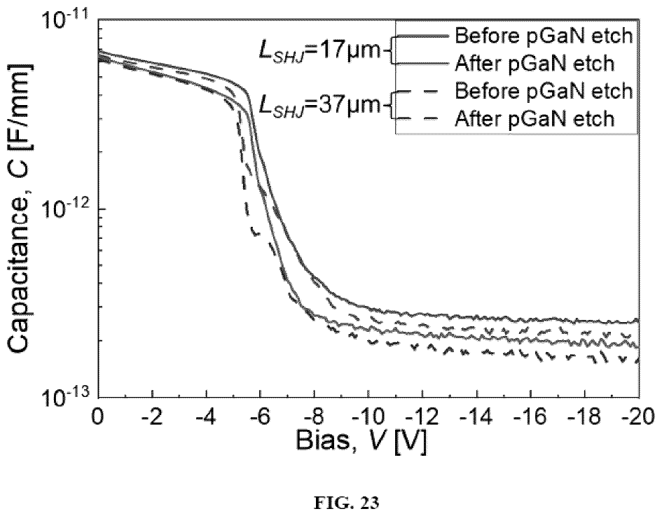

Capacitance-voltage (C-V) characteristics of the SHJ-SBDs were measured before and after the charge balance pGaN etch, as shown in FIG. 23. The plateaus correspond to the depletion of 2DEG and holes in the SHJ-SBDs. The charge balance etching led to lower capacitance floor beyond the pinch-off voltage. The lower capacitance floor indicates less mobile carriers in the structure, which is expected for a SHJ with better charge balance.

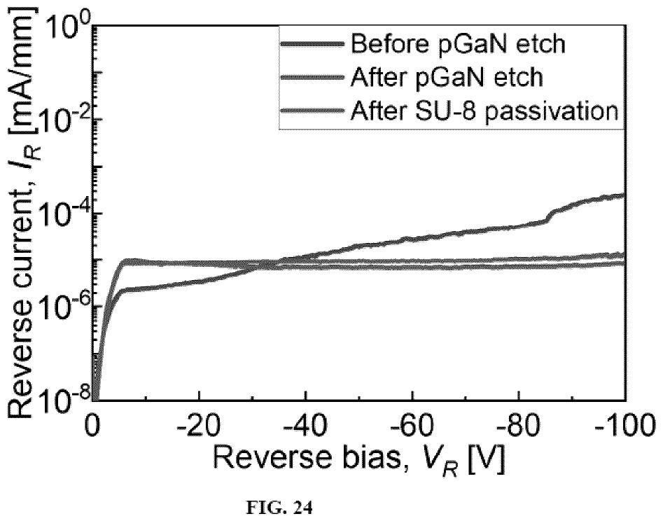

FIG. 24 shows reverse leakage characteristics of the same GaN SHJ-SBD measured before and after the pGaN charge balance etch, as well as after the SU-8 passivation. After the ˜20 nm pGaN etch, the I-V curve became flat, with lower leakage current at higher bias. The lower leakage at large reverse bias can be explained by the reduction of the peak E-field when there is better charge balance. Experiments on a companion sample showed that one more run of 20 nm pGaN etch increased the leakage current. These results suggested that one run of 20 nm pGaN etch yielded the best charge balance for our sample.

TCAD simulation suggested that the optimum pGaN thickness to reach the perfect charge balance was ˜150 nm for our doping design. Experimentally, the best charge balance was achieved with ˜206 nm thick remaining pGaN, after the p⁺GaN etch step with 24 nm of over etch into the pGaN and the one run of 20 nm pGaN etch. This discrepancy can be explained by donor-like surface states and/or sub-surface dry etch damages, which were not accounted for in our TCAD simulation.

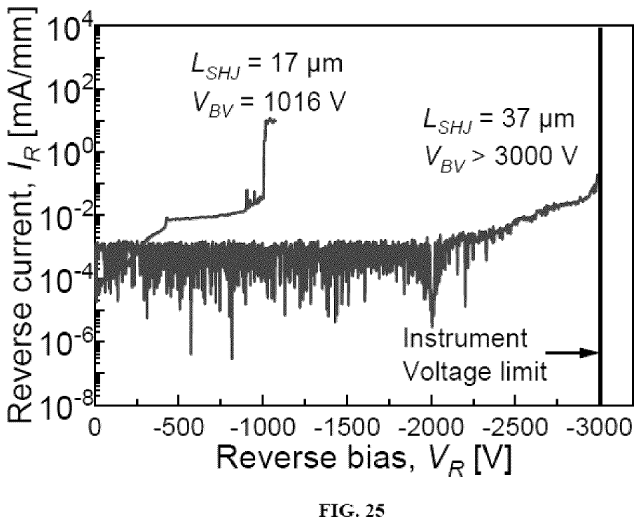

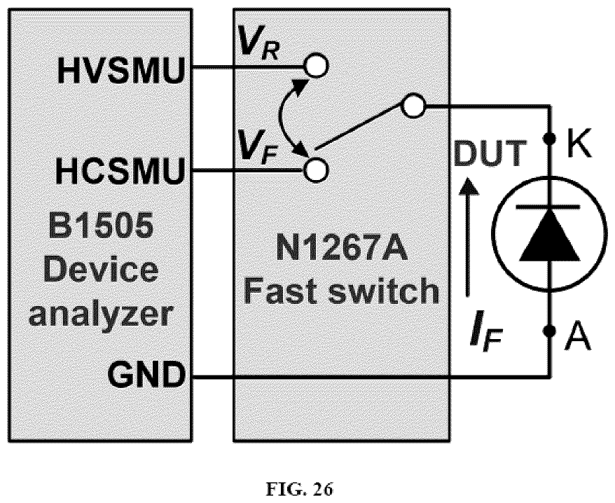

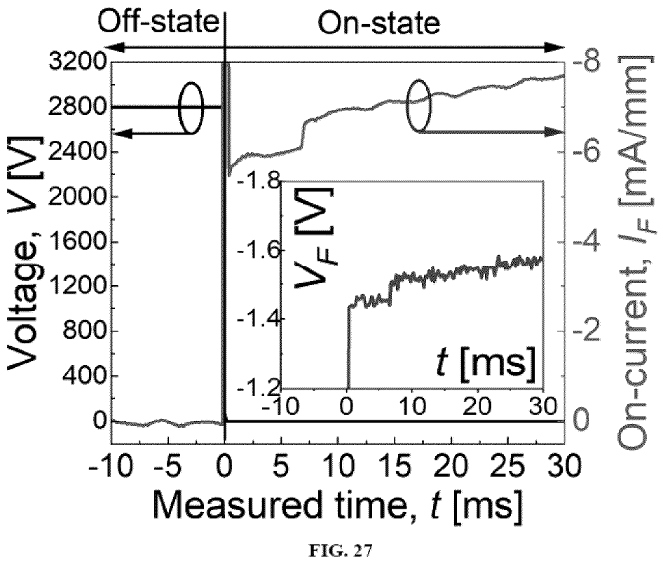

FIG. 25 shows the breakdown characteristics of the GaN SHJ-SBDs measured after the SU-8 passivation and with Fluorinert immersion. The device with L_{SHJ} of 17 μm showed a breakdown of 1016 V, while the device with L_{SHJ} of 37 μm did not show breakdown up to 3 kV, which is the upper limit of the measurement setup. Dynamic switching of the SHJ-SBD with 37 μm L_{SHJ} was performed using Keysight's N1267A fast switch unit configured with the B1505A parameter analyzer, as shown in FIG. 26. FIG. 27 shows the current and voltage waveforms of the SHJ-SBD switched from a reverse bias of 2.8 kV to a forward bias of 2V. The off and on times were 1 second and 30 ms, respectively. The inset of FIG. 27 shows a zoomed-in view of the voltage waveform at the on-state. The voltage drop across the diode was less than the applied bias of 2 V due to a current-dependent voltage drop across the N1267A.

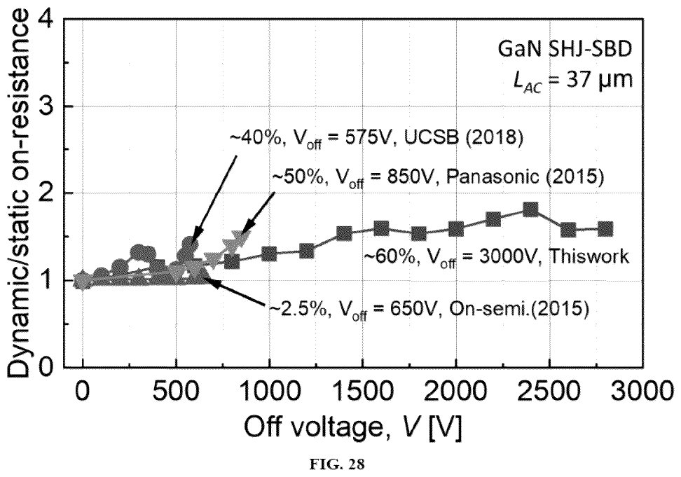

Differential on-resistance of the SHJ-SBD was calculated from two consecutive switching measurements with the same off-state bias, but different on-state biases of 1.5 V and 2.0 V. FIG. 28 shows extracted dynamic on-resistance, normalized to static on-resistance obtained from DC IV measurement, as a function of the off-state voltage. The degradation of dynamic on-resistance was no greater than 60% at 2.8 kV. The previous highest off-state voltage for dynamic on-resistance measurement of GaN devices was up to 850 V [41]. The SHJ-SBD's capability of being switched up to 2.8 kV with manageable degradation of dynamic on-resistance further attests the benefit of the charge-balanced SHJ design.

In this study, the inventors fabricated and characterized charge-balanced GaN SHJ-SBDs. The effects of charge balance were studied by adjusting the pGaN thickness. The charge-balance etch resulted in an increase of forward current, a decrease of output capacitance, and a substantial decrease of reverse leakage. The resulting GaN SHJ-SBDs showed scaling of breakdown voltage to over 3 kV. More importantly, state-of-the-art dynamic on-resistance was demonstrated up to 2.8 kV of off-state voltage, which is a significant improvement over the highest bias of 850 V for dynamic switching measurements of GaN devices reported previously [46]. It is contemplated that performance of GaN SHJ devices can be further improved by process optimization and the deployment of a multi-channel structure [38], [47].

This study relates to GaN super-heterojunction Schottky barrier diodes (SHJ-SBDs) with substantially improved performance. Metal-2DEG sidewall n-ohmic contacts were deployed to achieve low contact resistance of 0.75 Ω·mm, avoiding the risk of abnormally high contact resistance caused by inaccurate etch depth control. A pGaN notch formed near the cathode successfully eliminated excessive hole conduction caused by the sidewall n-ohmic contact. Isolation was improved by a high energy Al implantation step. The resulting SHJ-SBD exhibited a breakdown voltage of ˜12.5 kV and a specific on-resistance of 100.8 mΩ·cm².

The inventors have previously proposed [48] and experimentally demonstrated [49], [50] a charge-balanced GaN super-heterojunction Schottky barrier diode (SHJ-SBD) structure. The GaN SHJ-SBD features: (1) n-type delta-doping at the upper GaN/AlGaN interface provides electrons needed by the 2DEG channel; (2) p-type GaN forms a charge-balanced super junction with the n-type delta-doping; (3) an ohmic contact to the pGaN facilitates charging and discharging of holes with fast response.

The GaN SHJ-SBDs discussed above exhibited favorable dynamic switching performance up to 2.8 kV [49] and over 10 kV breakdown voltage (BV). [50] However, those devices encountered two challenges: (1) high n-ohmic contact resistance due to the difficulty in accurate control of ohmic recess depth; and (2) breakdown voltage being limited by the isolation rather than intrinsic junction breakdown.

In this study, the inventors overcome the two challenges, leading to another improvement in device performance. Sidewall metal-2DEG contact based on Ti/Al alloy was deployed to improve the ohmic contact resistance from 7.5 Ω·mm to 0.75 Ω·mm. The deployment of metal-2DEG sidewall contact does introduce a new problem: conformal metal coverage on the pGaN sidewall of the cathode side led to significant hole conduction between the anode and the cathode.

This conduction path was eliminated by etching a narrow notch across the pGaN near the cathode. The isolation was improved by adopting an implantation first process, using high energy Al+ to form a highly insulating isolation region. The improved device process yielded BV of 12.5 kV, highest breakdown voltage measured on GaN device so far, while having a low on-resistance of 100.8 mΩ·cm².

The epitaxial structure used for device fabrication was grown at Enkris by MOCVD on a sapphire substrate. From top to bottom, it consists of a 20 nm p⁺GaN layer, a 250 nm pGaN layer, a 70 nm unintentionally doped (UID) GaN spacer layer, a 10 nm Al_{0.25}Ga_{0.75}N barrier, a 300 nm UID GaN channel layer, and a GaN buffer layer. By introducing SiH₄ flow, Si delta-doping with a density of 7.5×10¹² cm⁻² was incorporated at the interface between UID GaN spacer and AlGaN barrier. Doping for the p⁺GaN and pGaN layers were realized by introducing Cp₂Mg flow, resulting in Mg densities of 1.5×10²⁰ cm⁻³ and 5×10¹⁷ cm⁻³, respectively.

The device fabrication started with activation annealing of pGaN. Isolation etch was then performed using Cl₂/BCl₃.based ICP-RIE with 600 nm etch depth. To improve isolation quality and suppress surface conduction, additional Al⁺ implantation was conducted, at an energy of 100 keV and a dose of 1×10¹⁵ cm⁻². 450 nm deep cathode and anode trenches on two opposite ends of the device active region were formed by Cl₂/BCl₃-based ICP-RIE, as shown in FIG. 29 at step (b). For n-ohmic formation, Ti/Al metal stack was evaporated on the cathode trench then annealed in N₂ ambient. For p-ohmic formation, Ni/Au metal stack was evaporated and annealed. Ni/Au thick metal stack was evaporated to form the Schottky contact on the cathode trench, as well as overlaying the n-ohmic and p-ohmic contacts.

To cut off the hole conduction path, 4-μm-wide and 260-nm-deep notch was formed by Cl₂/BCl₃-based ICP-RIE as shown in FIG. 29 step (f). To balance the charge between p- and n-type doping, one more setup of ICP-RIE etch was performed as shown in FIG. 29 at step (g), targeting ˜160 nm reduction of the pGaN thickness. Lastly, the devices were passivated using a 5-μm-thick SU-8.

The forward and reverse I-V characteristics were measured using a Keysight's B1505A power device parameter analyzer. The reverse I-V characteristics were further measured at the U.S. Naval Research Laboratory in a custom vacuum probe station, with the base pressure of 1×10⁻³ mTorr. A Bertan Series 225 High Voltage Power Supply was used to apply high voltage while current was measured across a 1 MOhm resistor using a Keithley 2000 multimeter.

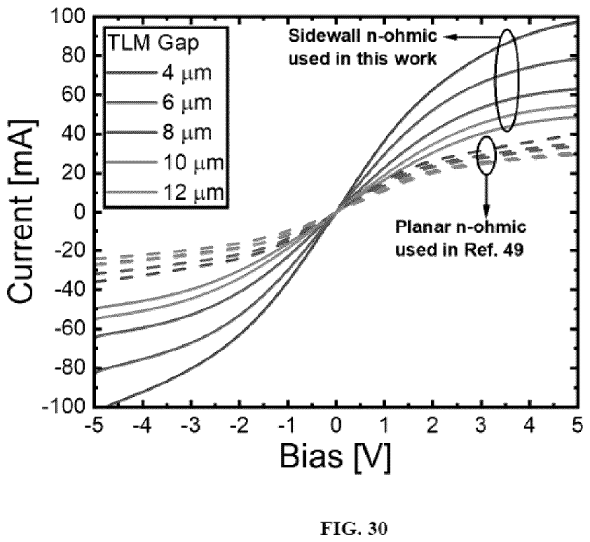

FIG. 30 shows a comparison of circular TLM I-V characteristics between this work and Ref. 49. The contact resistance in Ref. 49 was 7.5 Ω·mm, or 3.7×10⁻³ Ω·cm⁻². The higher than typical contact resistance value is attributed to under etching during the n-ohmic recess process. In this study, the contact resistance was improved by the sidewall contact design, resulting in 0.75 Ω·mm, or 3.51×10⁻⁶ Ω·cm².

While improving the n-ohmic contact resistance, the conformal sidewall contact introduced a hole conduction path in the pGaN region. If the Ti/Al n-ohmic metal had formed an ideal Schottky contact to the pGaN, the p-type Schottky junction should have blocked any hole conduction. Experimentally, significant reverse leakage from a PN diode test structure fabricated along with the SHJ Schottky diode on the same wafer was measured, as shown in FIG. 31. The high reverse leakage is possibly caused by defect-assisted tunneling at the interface between Ti/Al and etched pGaN sidewall. By etching a notch across the pGaN near the cathode, the hole conduction was eliminated, as evidenced by the reduction of PN diode leakage from 1.3×10⁻³ A/mm to ˜1.3×10⁻¹⁰ A/mm.

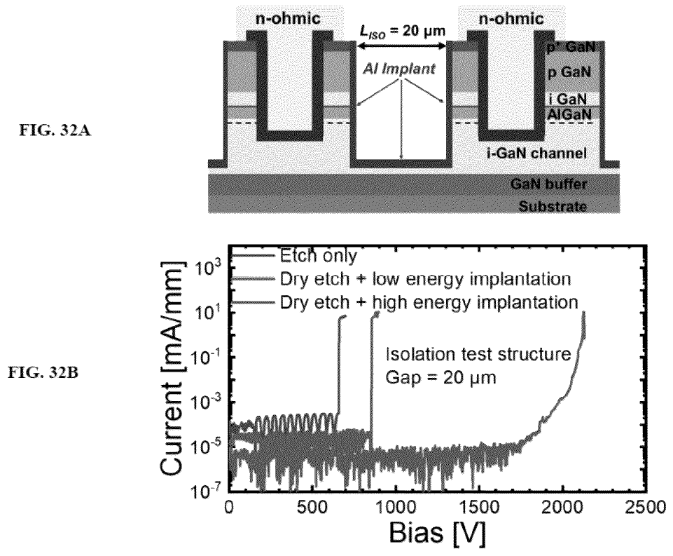

FIG. 32 shows I-V characteristics of isolation test structures (isolation gap=20 m), with dry etch only [49], dry etch plus low energy implantation [50], and dry etch plus high energy implantation described in this study. The improved isolation process is important for devices to demonstrate low reverse leakage and high breakdown voltage.

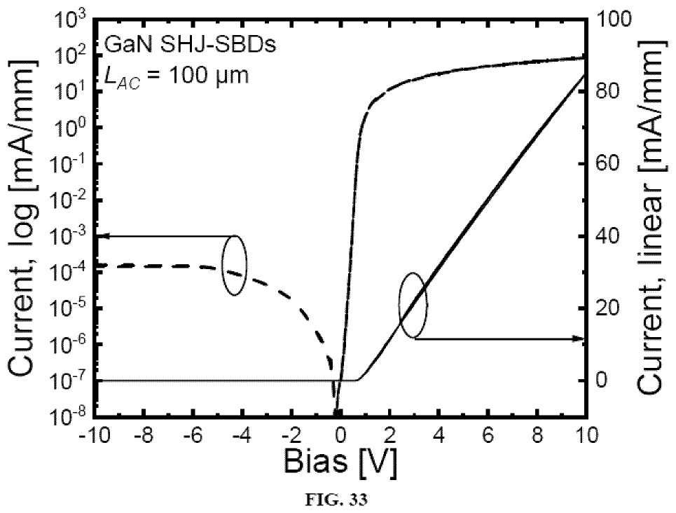

FIG. 33 shows I-V characteristics of a fabricated GaN SHJ-SBDs with L_{AC} of 100 μm and device width of 100 μm. The diode demonstrated a on/off current ratio of ˜10⁶. The forward turn-on voltage extracted at a forward current of 1 mA/mm was around 0.8 V, typical for metal-2DEG sidewall Schottky contacts. The extracted differential on-resistance values at 2 V forward bias was 91.7 Ω·mm. Using the entire semiconduction region between the cathode and the anode sidewalls as the device active area, the calculated specific on-resistance was 100.8 mΩ·cm².

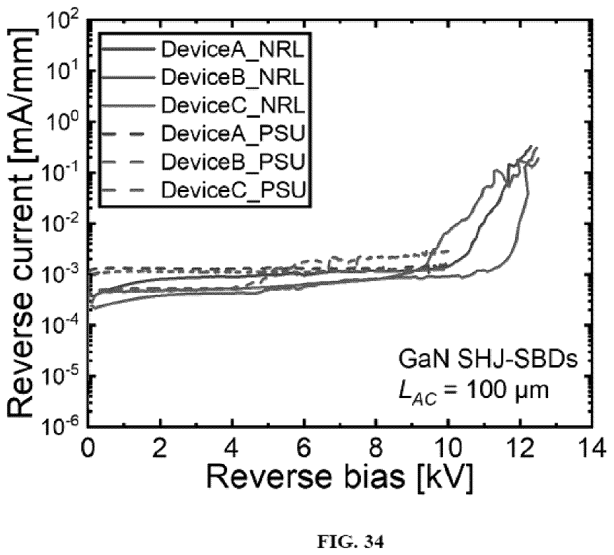

FIG. 34 shows reverse I-V characteristics of the same three GaN SHJ-SBDs were measured at PSU and NRL. All three devices showed low leakage of around 1 μA/mm up to the 10 kV measurement instrument limit of PSU's setup. Data collected at NRL's setup are very similar to data collected at PSU. The higher voltage range of NRL's setup allowed measurement of the breakdown voltage of ˜12.5 kV for all three diodes.

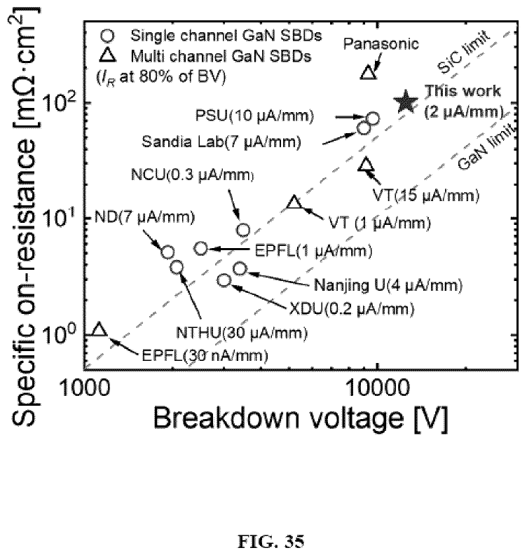

FIG. 35. Specific on-resistance (R_{ON,SP}) versus V_{B} benchmark of the GaN SHJ-SBDs against state-of-the-art lateral GaN SBDs. The performance of GaN SHJ-SBD described in this study is compared against state-of-the-art lateral GaN diodes in FIG. 35 [50]-[59]. The measured voltage blocking capability up to 12.5 kV, while maintaining a low on-resistance, attests the scalability of this technology to beyond 10-kV.

This study improved the performance of GaN SHJ-SBDs with metal-2DEG sidewall n-ohmic contact, pGaN notch formation, and high energy Al implantation. The measured breakdown voltage of 12.5 kV, while maintaining a low on-resistance of 91.7 Ω·mm or 100.8 mΩ·cm², demonstrated the scalability of charge-balanced GaN SHJ technology for medium voltage power electronics applications. While performing this study, the inventors noticed that Xiao et al. has just published a paper on 10-kV GaN SBDs, expanding the single-channel charge-balanced SHJ to multiple channels, while naming it differently as a reduced-surface field (RESURF) structure [59]. Progress made by Xiao et al. further shows the promise of this technology.

It will be understood that modifications to the embodiments disclosed herein can be made to meet a particular set of design criteria. For instance, any of the components of the device can be any suitable number or type of each to meet a particular objective. Therefore, while certain exemplary embodiments of the device and methods of using the same disclosed herein have been discussed and illustrated, it is to be distinctly understood that the invention is not limited thereto but can be otherwise variously embodied and practiced within the scope of the following claims.

It will be appreciated that some components, features, and/or configurations can be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiments. Thus, the components, features, and/or configurations of the various embodiments can be combined in any manner and such combinations are expressly contemplated and disclosed by this statement.

It will be appreciated by those skilled in the art that the present invention can be embodied in other specific forms without departing from the spirit or essential characteristics thereof. The presently disclosed embodiments are therefore considered in all respects to be illustrative and not restrictive. The scope of the invention is indicated by the appended claims rather than the foregoing description and all changes that come within the meaning, range, and equivalence thereof are intended to be embraced therein. Additionally, the disclosure of a range of values is a disclosure of every numerical value within that range, including the end points.

### REFERENCES

Each of the following references is incorporated by reference in its entirety.
[1] H. Amano et al. “The 2018 GaN power electronics roadmap,” J. Phys. D, Appl. Phys., vol. 51, March 2018, Art. no. 163001, doi: 10.1088/1361-6463/aaaf9d.
[2] F. Udrea, G. Deboy, and T. Fujihira, “Superjunction power devices, history, development, and future prospects,” IEEE Trans. Electron Devices, vol. 64, no. 3, pp. 720-734, March 2017, doi: 10.1109/TED.2017. 2658344.
[3] Z. Li and T. P. Chow, “Design and simulation of 5-20-kV GaN enhancement-mode vertical superjunction HEMT,” IEEE Trans. Electron Devices, vol. 60, no. 10, pp. 3230-3237, October 2013, doi: 10.1109/TED.2013.2266544.
[4] M. Xiao, R. Zhang, D. Dong, H. Wang, and Y. Zhang, “Design and simulation of GaN superjunction transistors with 2-DEG channels and ?n channels,” IEEE J. Emerg. Sel. Topics Power Electron., vol. 7, no. 3, pp. 1475-1484, September 2019, doi: 10.1109/JESTPE.2019.2912978.
[5] Y. Oonishi, A. Ooi, and T. Shimatou, “Superjunction MOSFET,” Fuji Electron. Rev., vol. 56, no. 2, pp. 65-68, 2000.
[6] S. Yamauchi, T. Shibata, S. Nogami, T. Yamaoka, Y. Hattori, and H. Yamaguchi, “200V super junction MOSFET fabricated by high aspect ratio trench filling,” in Proc. IEEE Int. Symp. Power Semicond. Devices IC's, June 2006, pp. 1-4, doi: 10.1109/ISPSD.2006.1666072.
[7] J. H. Ryou et al., “Surface treatment on the growth surface of semi-insulating GaN bulk substrate for III-nitride heterostructure field-effect transistors,” Phys. Status Solidi, vol. 5, no. 6, pp. 1849-1851, 2008, doi: 10.1002/pssc.200778698.
[8] Y.-Y. Wong et al., “Effect of nitridation on the regrowth interface of AlGaN/GaN structures grown by molecular beam epitaxy on GaN templates,” J. Electron. Mater., vol. 41, no. 8, pp. 2139-2144, 2012, doi: 10.1007/s11664-012-2150-2.
[9] H. Ishida et al., “Unlimited high breakdown voltage by natural super junction of polarized semiconductor,” IEEE Electron Device Lett., vol. 29, no. 10, pp. 1087-1089, October 2008, doi: 10.1109/LED. 2008.2002753.
[10] J. P. Ibbetson, P. T. Fini, K. D. Ness, S. P. DenBaars, J. S. Speck, and U. K. Mishra, “Polarization effects, surface states, and the source of electrons in AlGaN/GaN heterostructure field effect transistors,” Appl. Phys. Lett., vol. 77, no. 2, pp. 250-252, 2000, doi: 10.1063/1.126940.
[11] A. Xie, E. Beam, and Y. Cao, “Growth and characterization of GaN based multi-channel FETs,” in Proc. 235th ECS Meeting, Dallas, TX, USA, May 2019, p. 1277.
[12] B. Mazumder, M. H. Wong, C. A. Hurni, J. Y. Zhang, U. K. Mishra, and J. S. Speck, “Asymmetric interfacial abruptness in N-polar and Ga-polar GaN/AlN/GaN heterostructures,” Appl. Phys. Lett., vol. 101, no. 9, August 2012, doi: 10.1063/1.4748116.
[13] S. R. Lee et al., “In situ measurements of the critical thickness for strain relaxation in AlGaN/GaN heterostructures,” Appl. Phys. Lett., vol. 85, no. 25, pp. 6164-6166, 2004, doi: 10.1063/1.1840111.
[14] H. V. Stanchu et al., “Local strain and crystalline defects in GaN/AlGaN/GaN(0001) heterostructures induced by compositionally graded AlGaN buried layers,” Cryst. Growth Des., vol. 19, no. 1, pp. 200-210, 2019, doi: 10.1021/acs.cgd.8b01267.
[15] S.-H. Ryu et al., “10-kV, 123-mΩ·cm² 4H-SiC power DMOSFETs,” IEEE Electron Device Lett., vol. 25, no. 8, pp. 556-558, August 2004, doi: 10.1109/LED.2004.832122.
[16] J. Chen and W. D. Brewer, “Ohmic contacts on p-GaN,” Adv. Electron. Mater., vol. 1, no. 8, 2015, Art. no. 1500113, doi: 10.1002/aelm.201500113.
[17] S. Hautakangas et al., “Vacancy defects as compensating centers in Mg-Doped GaN,” Phys. Rev. Lett., vol. 90, no. 13, 2003, Art. no. 137402, doi: 10.1103/PhysRevLett.90.137402.
[18] X. A. Cao et al., “Electrical effects of plasma damage in p-GaN,” Appl. Phys. Lett., vol. 75, no. 17, pp. 2569-2571, October 1999, doi: 10.1063/1.125080.
[19] D. Shibata et al., “1.7 kV/1.0 mK cm2 normally-off vertical GaN transistor on GaN substrate with regrown p-GaN/AlGaN/GaN semipolar gate structure,” in IEDM Tech. Dig., December 2016, pp. 10.1.1-10.1.4, doi: 10.1109/IEDM.2016.7838385.
[20] D. Shibata et al., “GaN-based multi-junction diode with low reverse leakage current using p-type barrier controlling layer,” in IEDM Tech. Dig., December 2011, pp. 26.2.1-26.2.4, doi: 10.1109/IEDM. 2011.6131616.
[21] M. Farahmand et al., “Monte Carlo simulation of electron transport in the III-nitride wurtzite phase materials system: Binaries and ternaries,” IEEE Trans. Electron Devices, vol. 48, no. 3, pp. 535-542, March 2001, doi: 10.1109/16.906448.
[22] S. Selberherr, Analysis and Simulation of Semiconductor Devices, New York, NY, USA: Springer-Verlag, 1984.
[23] Z. Z. Bandić, P. M. Bridger, E. C. Piquette, and T. C. McGill, “Electron diffusion length and lifetime in p-type GaN,” Appl. Phys. Lett., vol. 73, no. 22, pp. 3276-3278, 1998, doi: 10.1063/1.122743.
[24] Z. Z. Bandić, P. M. Bridger, E. C. Piquette, and T. C. McGill, “Minority carrier diffusion length and lifetime in GaN,” Appl. Phys. Lett., vol. 72, no. 24, pp. 3166-3168, 1998, doi: 10.1063/1.121581.
[25] TCAD Examples: Blue Single Quantum Well GaNLED. Accessed: Aug. 28, 2019. [Online]. Available: https://www.silvaco.com/examples/tcad/section22/example 3
[26] T. Oka, T. Ina, Y. Ueno, and J. Nishii, “Over 10 a operation with switching characteristics of 1.2 kV-class vertical GaN trench MOSFETs on a bulk GaN substrate,” Proc. Int. Symp. Power Semicond. Devices ICs, vol. 2016-July, pp. 459-462, 2016, doi: 10.1109/ISPSD.2016.7520877.
[27] Y. F. Wu, J. Gritters, L. Shen, R. P. Smith, and B. Swenson, “KV-class GaN-on-Si HEMTs enabling 99% efficiency converter at 800 v and 100 kHz,” IEEE Trans. Power Electron., vol. 29, no. 6, pp. 2634-2637, 2014, doi: 10.1109/TPEL.2013.2284248.
[28] Y. Uemoto, D. Shibata, M. Yanagihara, H. Ishida, H. Matsuo, S. Nagai, N. Batta, M. Li, T. Ueda, T. Tanaka, and D. Ueda, “8300V blocking voltage AlGaN/GaN power HFET with thick poly-AlN passivation,” Tech. Dig.—Int. Electron Devices Meet. IEDM, pp. 861-864, 2007, doi: 10.1109/IEDM.2007.4419085.
[29] H. Ishida, D. Shibata, M. Yanagihara, Y. Uemoto, H. Matsuo, T. Ueda, T. Tanaka, and D. Ueda, “Unlimited high breakdown voltage by natural super junction of polarized semiconductor,” IEEE Electron Device Lett., vol. 29, no. 10, pp. 1087-1089, 2008, doi: 10.1109/LED.2008.2002753.
[30] A. Colón, E. A. Douglas, A. J. Pope, B. A. Klein, C. A. Stephenson, M. S. Van Heukelom, A. Tauke-Pedretti, and A. G. Baca, “Demonstration of a 9 kV reverse breakdown and 59 mΩ-cm2 specific on-resistance AlGaN/GaN Schottky barrier diode,” Solid. State. Electron., vol. 151, no. September 2018, pp. 47-51, 2019, doi: 10.1016/j.sse.2018.10.009.
[31] S. Yang, S. Han, K. Sheng, and K. J. Chen, “Dynamic On-Resistance in GaN Power Devices: Mechanisms, Characterizations, and Modeling,” IEEE J. Emerg. Sel. Top. Power Electron., vol. 7, no. 3, pp. 1425-1439, 2019, doi: 10.1109/JESTPE.2019.2925117.
[32] R. Chu, A. Corrion, M. Chen, R. Li, D. Wong, D. Zehnder, B. Hughes, and K. Boutros, “1200-V normally off GaN-on-Si field-effect transistors with low dynamic on-resistance,” IEEE Electron Device Lett., vol. 32, no. 5, pp. 632-634, 2011, doi: 10.1109/LED.2011.2118190.
[33] Y. Cao, R. Chu, R. Li, M. Chen, R. Chang, and B. Hughes, “High-voltage vertical GaN Schottky diode enabled by low-carbon metal-organic chemical vapor deposition growth,” Appl. Phys. Lett., vol. 108, no. 6, 2016, doi: 10.1063/1.4941814.
[34] H. Ohta, K. Hayashi, F. Horikiri, M. Yoshino, T. Nakamura, and T. Mishima, “5.0 kV breakdown-voltage vertical GaN p-n junction diodes,” Jpn. J. Appl. Phys., vol. 57, no. 4, pp. 3-7, 2018, doi: 10.7567/JJAP.57.04FG09.
[35] I. C. Kizilyalli, T. Prunty, and O. Aktas, “4-kV and 2.8-mΩ-cm2 Vertical GaN p-n Diodes with Low Leakage Currents,” IEEE Electron Device Lett., vol. 36, no. 10, pp. 1073-1075, 2015, doi: 10.1109/LED.2015.2474817.
[36] A. Nakajima, K. Adachi, M. Shimizu, and H. Okumura, “Improvement of unipolar power device performance using a polarization junction,” Appl. Phys. Lett., vol. 89, no. 19, pp. 87-90, 2006, doi: 10.1063/1.2372758.
[37] A. Nakajima, Y. Sumida, M. H. Dhyani, H. Kawai, and E. M. Narayanan, “GaN-based super heterojunction field effect transistors using the polarization junction concept,” IEEE Electron Device Lett., vol. 32, no. 4, pp. 542-544, 2011, doi: 10.1109/LED.2011.2105242.
[38] S. Han, J. Song, and R. Chu, “Design of GaN/AlGaN/GaN Super-Heterojunction Schottky Diode,” IEEE Trans. Electron Devices, vol. 67, no. 1, pp. 69-74, 2020, doi: 10.1109/TED.2019.2953843.
[39] O. S. Koksaldi, J. Haller, H. Li, B. Romanczyk, M. Guidry, S. Wienecke, S. Keller, and U. K. Mishra, “N-Polar GaN HEMTs exhibiting record breakdown voltage over 2000 v and Low Dynamic On-Resistance,” IEEE Electron Device Lett., vol. 39, no. 7, pp. 1014-1017, 2018, doi: 10.1109/LED.2018.2834939.
[40] P. Moens, P. Vanmeerbeek, A. Banerjee, J. Guo, C. Liu, P. Coppens, A. Salih, M. Tack, M. Caesar, M. J. Uren, M. Kuball, M. Meneghini, G. Meneghesso, and E. Zanoni, “On the impact of carbon-doping on the dynamic Rₒₙ and off-state leakage current of 650V GaN power devices,” Proc. Int. Symp. Power Semicond. Devices ICs, vol. 2015-June, pp. 37-40, 2015, doi: 10.1109/ISPSD.2015.7123383.
[41] S. Kaneko, M. Kuroda, M. Yanagihara, A. Ikoshi, H. Okita, T. Morita, K. Tanaka, M. Hikita, Y. Uemoto, S. Takahashi, and T. Ueda, “Current-collapse-free operations up to 850 V by GaN-GIT utilizing hole injection from drain,” in 2015 IEEE 27th International Symposium on Power Semiconductor Devices & IC's (ISPSD), 2015, pp. 41-44, doi: 10.1109/ISPSD.2015.7123384.
[42] L. Shen, Y. Pei, L. McCarthy, C. Poblenz, A. Corrion, N. Fichtenbaum, S. Keller, S. P. Denbaars, J. S. Speck, and U. K. Mishra, “Deep-recessed GaN HEMTs using selective etch technology exhibiting high microwave performance without surface passivation,” IEEE MTT-S Int. Microw. Symp. Dig., pp. 623-626, 2007, doi: 10.1109/MWSYM.2007.379978.
[43] W. Li, D. Ji, R. Tanaka, S. Mandal, M. Laurent, and S. Chowdhury, “Demonstration of GaN Static Induction Transistor (SIT) Using Self-Aligned Process,” IEEE J. Electron Devices Soc., vol. 5, no. 6, pp. 485-490, 2017, doi: 10.1109/JEDS.2017.2751065.
[44] H. Ishida, D. Shibata, H. Matsuo, M. Yanagihara, Y. Uemoto, T. Ueda, T. Tanaka, and D. Ueda, “GaN-based natural super junction diodes with multi-channel structures,” Tech. Dig.—Int. Electron Devices Meet. IEDM, pp. 1-4, 2008, doi: 10.1109/IEDM.2008.4796636.
[45] M. Zhu, B. Song, M. Qi, Z. Hu, K. Nomoto, X. Yan, Y. Cao, W. Johnson, E. Kohn, D. Jena, S. Member, H. G. Xing, and S. Member, “1.9-kV AlGaN/GaN Lateral Schottky Barrier Diodes on Silicon,” IEEE Electron Device Lett., vol. 36, no. 4, pp. 375-377, 2015.
[46] S. Kaneko, M. Kuroda, M. Yanagihara, A. Ikoshi, H. Okita, T. Morita, K. Tanaka, M. Hikita, Y. Uemoto, S. Takahashi, and T. Ueda, “Current-collapse-free operations up to 850 V by GaN-GIT utilizing hole injection from drain,” in 2015 IEEE 27th International Symposium on Power Semiconductor Devices & IC's (ISPSD), 2015, pp. 41-44, doi: 10.1109/ISPSD.2015.7123384.
[47] R. Chu, “GaN power switches on the rise: Demonstrated benefits and unrealized potentials,” Appl. Phys. Lett., vol. 116, no. 9, 2020, doi: 10.1063/1.5133718.
[48] S. Han, J. Song, and R. Chu, “Design of GaN/AlGaN/GaN Super-Heterojunction Schottky Diode,” IEEE Trans. Electron Devices, vol. 67, no. 1, pp. 69-74, 2020, doi: 10.1109/TED.2019.2953843.
[49] S.-W. Han, J. Song, S. H. Yoo, Z. Ma, R. M. Lavelle, D. W. Snyder, J. M. Redwing, T. N. Jackson, and R. Chu, “Experimental Demonstration of Charge-Balanced GaN Super-Heterojunction Schottky Barrier Diode Capable of 2.8 kV Switching,” IEEE Electron Device Lett., vol. 41, no. 12, pp. 1758-1761, 2020, doi: 10.1109/LED.2020.3029619.
[50] S. Han, J. Song, and R. Chu, “GaN Super-Heterojunction Schottky Barrier Diode with Over 10 kV Blocking Voltage,” 2021.
[51] A. Colón, E. A. Douglas, A. J. Pope, B. A. Klein, C. A. Stephenson, M. S. Van Heukelom, A. Tauke-Pedretti, and A. G. Baca, “Demonstration of a 9 kV reverse breakdown and 59 mΩ-cm2 specific on-resistance AlGaN/GaN Schottky barrier diode,” Solid. State. Electron., vol. 151, no. July 2018, pp. 47-51, 2019, doi: 10.1016/j.sse.2018.10.009.
[52] G. Y. Lee, H. H. Liu, and J. I. Chyi, “High-performance AlGaN/GaN schottky diodes with an AlGaN/AlN buffer layer,” IEEE Electron Device Lett., vol. 32, no. 11, pp. 1519-1521, 2011, doi: 10.1109/LED.2011.2164610.
[53] C. W. Tsou, K. P. Wei, Y. W. Lian, and S. S. H. Hsu, “2.07-kV AlGaN/GaN Schottky Barrier Diodes on Silicon with High Baliga's Figure-of-Merit,” IEEE Electron Device Lett., vol. 37, no. 1, pp. 70-73, 2016, doi: 10.1109/LED.2015.2499267.
[54] M. Zhu, B. Song, M. Qi, Z. Hu, K. Nomoto, X. Yan, Y. Cao, W. Johnson, E. Kohn, D. Jena, S. Member, H. G. Xing, and S. Member, “1.9-kV AlGaN/GaN Lateral Schottky Barrier Diodes on Silicon,” IEEE Electron Device Lett., vol. 36, no. 4, pp. 375-377, 2015.
[55] J. Ma and E. Matioli, “2 kV slanted tri-gate GaN-on-Si Schottky barrier diodes with ultra-low leakage current,” Appl. Phys. Lett., vol. 112, no. 5, 2018, doi: 10.1063/1.5012866.
[56] J. Ma, G. Kampitsis, P. Xiang, K. Cheng, and E. Matioli, “Multi-Channel Tri-Gate GaN Power Schottky Diodes with Low ON-Resistance,” IEEE Electron Device Lett., vol. 40, no. 2, pp. 275-278, 2019, doi: 10.1109/LED.2018.2887199.
[57] T. Zhang, J. Zhang, H. Zhou, Y. Wang, T. Chen, K. Zhang, Y. Zhang, K. Dang, Z. Bian, J. Zhang, S. Xu, X. Duan, J. Ning, and Y. Hao, “A >3 kV/2.94 mΩ cm2 and Low Leakage Current with Low Turn-On Voltage Lateral GaN Schottky Barrier Diode on Silicon Substrate with Anode Engineering Technique,” IEEE Electron Device Lett., vol. 40, no. 10, pp. 1583-1586, 2019, doi: 10.1109/LED.2019.2933314.
[58] H. Ishida, D. Shibata, H. Matsuo, M. Yanagihara, Y. Uemoto, T. Ueda, T. Tanaka, and D. Ueda, “GaN-based natural super junction diodes with multi-channel structures,” Tech. Dig.—Int. Electron Devices Meet. IEDM, 2008, doi: 10.1109/IEDM.2008.4796636.
[59] M. Xiao, Y. Ma, K. Liu, K. Cheng, and Y. Zhang, “10 kV, 39 mΩ·cm 2 Multi-Channel AlGaN/GaN Schottky Barrier Diodes,” vol. 3106, no. c, pp. 2-5, 2021, doi: 10.1109/LED.2021.3076802.

What is claimed is:

1. A two-dimensional electron gas (2DEG) channel for a super-heterojunction structure, comprising:
a n-type modulation doped layer;
at least one p-type layer; and
wherein the n-type modulation doped layer is adjacent the at least one p-type layer to generate a charge balanced super-heterojunction region.

2. The 2DEG channel of claim 1, wherein:
the n-type modulation doped layer is formed by any one or combination of:
n-type barrier layer doping; and
n-type δ-doping in the barrier layer; and n-type doping at an interface between the barrier layer and the at least one p-type layer; and
n-type δ-doping at an interface between the barrier layer and the at least one p-type layer.

3. The 2DEG channel of claim 1, wherein:
the at least one p-type layer comprises at least two p-type layers;
a first p-type layer comprises GaAs, GaN, or GaOₓ;
a second p-type layer comprises AlGaAs, AlGaN, or AlGaOₓ.

4. The 2DEG channel of claim 1, wherein:
p-type dopant for the p-type layer comprises any one or combination of Mg, Li, Na, K, Be, Zn Ca, and Be.

5. A diode, comprising:
at least one 2DEG channel of claim 1.

6. A diode, comprising:
a plurality of 2DEG channels of claim 1.

7. A transistor, comprising:
at least one diode having the 2DEG channel of claim 1.

8. A diode, comprising:
a super-heterojunction structure having at least one two-dimensional electron gas (2DEG) channel;
the at least one 2DEG channel, comprising:
a n-type modulation doped layer;
at least one p-type layer; and
wherein the n-type modulation doped layer is adjacent the at least one p-type layer to generate a charge balanced super-heterojunction region;
an anode; and
a cathode.

9. The diode of claim 8, wherein:
the anode is configured as a Schottky contact and a p-ohmic contact.

10. The diode of claim 9, wherein:
the Schottky contact forms a Schottky contact between the anode and the at least one 2DEG channel.

11. The diode of claim 9, wherein:
the p-ohmic contact forms an ohmic contact between an p-ohmic metal and the at least one p-type layer.

12. The diode of claim 9, wherein:
a p+ layer formed between a p-ohmic metal and the at least one p-type layer.

13. The diode of claim 9, wherein:
the Schottky contact and the p-ohmic contact are electrically connected.

14. The diode of claim 8, wherein:
the cathode is configured as a n-ohmic contact.

15. The diode of claim 14, wherein:
the n-ohmic contact forms an ohmic contact between the cathode and the at least one 2DEG channel.

16. The diode of claim 8, comprising:
a notch configured to reduce or eliminate hole conduction between the anode and cathode.

17. The diode of claim 16, wherein:
the notch is a void formed by etching or a region formed by plasma treatment.

18. The diode of claim 8, comprising:
a plurality of 2DEG channels.

19. A transistor, comprising:
a least one diode of claim 8.

20. The diode of claim 8, comprising:
a p-n junction comprising a p-type region and a n-type region;
the anode in electrical connection with the p-type region;
the cathode in electrical connection with the n-type region; and
the anode is configured as a p-ohmic contact.

21. A diode, comprising:
a super-heterojunction structure having a charge balance region, the charge balance region comprising:
a passivation layer;
a p-type layer adjacent the passivation layer;
an unintentionally doped (UID) spacer layer adjacent the p-type layer;
an UID barrier layer adjacent the UID spacer layer;
a n-type modulation doped layer between the UID spacer layer and the UID barrier layer;
an UID channel layer adjacent the UID barrier layer; and
a buffer layer adjacent the UID channel layer;
an anode and;
a cathode.

22. The diode of claim 21, wherein:
the anode is configured as a Schottky contact and a p-ohmic contact.

23. The diode of claim 22, wherein:
the Schottky contact forms a Schottky contact between the anode and at least one two-dimensional electron gas channel.

24. The diode of claim 22, wherein:
the p-ohmic contact forms an ohmic contact between a p-ohmic metal and the at least one p-type layer.

25. The diode of claim 22, wherein:
a p+ layer formed between a p-ohmic metal and the at least one p-type layer.

26. The diode of claim 22, wherein:
the Schottky contact and the p-ohmic contact are electrically connected.

27. The diode of claim 21, wherein:
the cathode is configured as a n-ohmic contact.

28. The diode of claim 27, wherein:
the n-ohmic contact forms a ohmic contact between the cathode and at least one two-dimensional electron gas channel.

29. The diode of claim 21, comprising:
a plurality of 2DEG channels.

30. The diode of claim 21, comprising:
a p-n junction comprising a p-type region and a n-type region;
the anode in electrical connection with the p-type region;
the cathode in electrical connection with the n-type region; and
the anode is configured as a p-ohmic contact.

31. A transistor, comprising:
a least one diode of claim 21.
